(19) United States
(12) Patent Application Publication
(10) Pub. No.: US 2025/0107368 A1
(43) Pub. Date: Mar. 27, 2025

(54) DISPLAY DEVICE

(71) Applicant: Samsung Display Co., LTD., Yongin-si (KR)

(72) Inventors: SEUNG-SOO RYU, Yongin-si (KR); HONGAM KIM, Yongin-si (KR); KIKYUNG YOUK, Yongin-si (KR)

(21) Appl. No.: 18/886,084

(22) Filed: Sep. 16, 2024

(30) Foreign Application Priority Data
Sep. 27, 2023 (KR) 10-2023-0130176

(51) Int. Cl. H10K 59/131; H10K 59/88

(52) U.S. Cl. CPC H10K 59/131; H10K 59/88

(57) ABSTRACT

A display device includes a display panel including pixels, first output pads arranged along a first direction, second output pads spaced apart from the first output pads in a second direction, and input pads spaced apart in the second direction from the second output pads and arranged along the first direction; a driver chip including first output bumps arranged along the first direction and coupled to the first output pads, second output bumps spaced apart in the second direction at a first distance from the first output bumps and coupled to the second output pads, and input bumps spaced apart in the second direction from the second output bumps and coupled to the input pads; and a dummy pattern between the second output pads and the input pads and in contact with the display panel and the driver chip. The dummy pattern includes a dielectric material.

This application claims priority to Korean Patent Application No. 10-2023-0130176, filed on Sep. 27, 2023, and all the benefits accruing therefrom under 35 U.S.C. § 119, the content of which in its entirety is herein incorporated by reference.

### BACKGROUND

### 1. Field

Embodiments of the disclosure relate to a display device, and more particularly, to a display device where a driver chip is disposed (e.g., mounted) on a substrate.

### 2. Description of the Related Art

Various types of display devices used for multimedia apparatuses such as televisions, mobile phones, tablet computers, navigation systems, and game consoles are being developed. Such device devices include a plurality of electronic components. The electronic components include a display panel, a driver chip, a circuit board, and the like. These electronic components are electrically connected through various ways.

### SUMMARY

Embodiments of the disclosure provides a display device including a driver chip disposed (e.g., mounted) without the occurrence of crack or fracture.

In an embodiment of the disclosure, a display device may include: a display panel that includes a plurality of pixels, a plurality of first row output pads electrically connected to the plurality of pixels and arranged along a first direction, a plurality of second row output pads spaced apart from the plurality of first row output pads in a second direction intersecting the first direction, and a plurality of input pads spaced apart in the second direction from the plurality of second row output pads and arranged along the first direction; a driver chip that includes a plurality of first row output bumps arranged along the first direction and coupled to the plurality of first row output pads, a plurality of second row output bumps spaced apart in the second direction at a first distance from the plurality of first row output bumps and coupled to the plurality of second row output pads, and a plurality of input bumps spaced apart in the second direction from the plurality of second row output bumps and coupled to the plurality of input pads; and a dummy pattern between the plurality of second row output pads and the plurality of input pads and in contact with each of the display panel and the driver chip, the dummy pattern including a dielectric material.

In an embodiment, ones of the plurality of first row output bumps and the plurality of second row output bumps may include: a plurality of first bumps aligned along the first direction; and a plurality of second bumps aligned along the first direction and shifted in the second direction at a third distance from the plurality of first bumps, the third distance being less than the first distance.

In an embodiment, the dummy pattern may include: a plurality of first dummy members aligned along the first direction; and a plurality of second dummy members aligned along the first direction and shifted in the second direction at a predetermined distance from the plurality of first dummy members.

In an embodiment, the dummy pattern may be spaced apart in the second direction at a second distance from the plurality of second row output bumps. The second distance may be greater than the first distance.

In an embodiment, the plurality of first dummy members and the plurality of second dummy members may be alternately arranged along the first direction. A distance in the second direction between the plurality of first dummy members and the plurality of first bumps of the plurality of second row output bumps may be the same as a distance in the second direction between the plurality of second dummy members and the plurality of second bumps of the plurality of second row output bumps.

In an embodiment, a width in the first direction of each of the plurality of first dummy members and the plurality of second dummy members may be the same as or less than a width in the first direction of each of the plurality of first row output bumps and the plurality of second row output bumps.

In an embodiment, the plurality of first bumps and the plurality of first dummy members may be aligned along a first baseline direction that intersects the first direction. The plurality of second bumps and the plurality of second dummy members may be aligned along a second baseline direction that intersects the first direction.

In an embodiment, the dummy pattern may be provided in plural. The plurality of dummy patterns may be arranged along the second direction. At least one of the plurality of dummy patterns may be more adjacent to the plurality of input pads than to the plurality of second row output pads.

In an embodiment, each of the plurality of dummy patterns may include a plurality of dummy members. Ones of the plurality of dummy members may be aligned with the plurality of first row output bumps or the plurality of second row output bumps in a direction that intersects the first direction. Others of the plurality of dummy members may be aligned with the plurality of input pads in the direction that intersects the first direction.

In an embodiment, the dummy pattern may be provided in plural. In the second direction, one of the plurality of dummy patterns may overlap a plurality of pads.

In an embodiment, in the first direction, the plurality of dummy patterns may have a single pattern shape.

In an embodiment, a height of the dummy pattern may be greater than heights of the plurality of first and second row output pads.

In an embodiment, the display device may further include an input sensor on the display panel. Each of the display panel and the input sensor may include: first, second, and third dielectric layers; a first conductive layer between the first dielectric layer and the second dielectric layer; and a second conductive layer between the second dielectric layer and the third dielectric layer. The dummy pattern may include: a first dummy layer that includes a dielectric material the same as a material of the first dielectric layer of the display panel; a second dummy layer on the first dummy layer, the second dummy layer including a material the same as a material of the second dielectric layer of the display panel; and a third dummy layer on the second dummy layer, the third dummy layer including a material the same as a material of the third dielectric layer of the input sensor.

In an embodiment, lateral surfaces of the first, second, and third dummy layers may be aligned with each other.

In an embodiment, a step difference may be defined between the lateral surfaces of two neighboring ones of the first, second, and third dummy layers.

In an embodiment, the second dummy layer may cover the lateral surface of the first dummy layer. The third dummy layer may cover the lateral surface of the second dummy layer.

In an embodiment of the disclosure, a display device may include: a display panel that includes a plurality of pixels, a plurality of first row output pads electrically connected to the pixels and arranged along a first direction, a plurality of second row output pads spaced apart from the plurality of first row output pads in a second direction intersecting the first direction, and a plurality of input pads spaced apart in the second direction from the plurality of second row output pads and arranged along the first direction; a driver chip that includes a plurality of first row output bumps arranged along the first direction and coupled to the plurality of first row output pads, a plurality of second row output bumps spaced apart in the second direction at a first distance from the plurality of first row output bumps and coupled to the plurality of second row output pads, and a plurality of input bumps spaced apart in the second direction from the plurality of second row output bumps and coupled to the plurality of input pads; and a dummy pattern between the plurality of second row output pads and the plurality of input pads, in a plan view, and in contact with each of the display panel and the driver chip. The dummy pattern may be spaced apart in the second direction at a second distance from the plurality of second row output bumps. The second distance may be greater than the first distance.

In an embodiment, the dummy pattern may include a plurality of dummy members. The plurality of dummy members may include: a plurality of first dummy members aligned along the first direction; and a plurality of second dummy members aligned along the first direction and shifted in the second direction at a predetermined distance from the plurality of first dummy members.

In an embodiment, ones of the plurality of first row output bumps and the plurality of second row output bumps may include: a plurality of first bumps aligned along the first direction; and a plurality of second bumps aligned along the first direction and shifted in the second direction at a third distance from the plurality of first bumps, the third distance being less than the first distance. A distance in the second direction between the plurality of first dummy members and the plurality of first bumps of the plurality of second row output bumps may be the same as a distance in the second direction between the plurality of second dummy members and the plurality of second bumps of the plurality of second row output bumps.

In an embodiment, the plurality of first bumps and the plurality of first dummy members may be aligned along a direction that intersects the first direction. The plurality of second bumps and the plurality of second dummy members may be aligned along the direction that intersects the first direction.

### BRIEF DESCRIPTION OF DRAWINGS

The above and other exemplary embodiments, advantages and features of this disclosure will become more apparent by describing in further detail exemplary embodiments thereof with reference to the accompanying drawings, in which:

FIG. 1A illustrates a perspective view showing an embodiment of an electronic device according to the invention.

FIG. 1B illustrates an exploded perspective view showing an embodiment of an electronic device according to the invention.

FIGS. 2A and 2B illustrate cross-sectional views showing an embodiment of a display device according to the invention.

FIG. 3A illustrates a plan view showing an embodiment of a display panel according to the invention.

FIG. 3B illustrates a cross-sectional view showing an embodiment of a display device according to the invention.

FIG. 4 illustrates an exploded perspective view showing an embodiment of a bonding region of a display device according to the invention.

FIGS. 5A and 5B illustrate plan views showing an embodiment of a chip region of a display device according to the invention.

FIG. 6A illustrates a simplified enlarged cross-sectional view showing a comparative example of a chip region of a display device.

FIG. 6B illustrates a graph showing a stress applied to a comparative example of a chip region of a display device.

FIG. 7 illustrates a simplified enlarged cross-sectional view showing an embodiment of a chip region of a display device according to the invention.

FIG. 8 illustrates an enlarged cross-sectional view showing an embodiment of a chip region of a display device according to the invention.

FIGS. 9A and 9B illustrate enlarged cross-sectional views of an area F9 of an embodiment of a dummy pattern of a display device of FIG. 8 according to the invention.

FIGS. 10A to 10D illustrate simplified views showing an embodiment of an arrangement relationship between bumps and dummy patterns of a display device according to the invention.

### DETAILED DESCRIPTION OF EMBODIMENTS

In this description, when a certain component (or region, layer, portion, etc.) is referred to as being “on”, “connected to”, or “coupled to” other component(s), the certain component may be directly on, directly connected to, or directly coupled to the other component(s) or at least one intervening component may be present therebetween.

Like numerals indicate like components. Moreover, in the drawings, thicknesses, ratios, and dimensions of components are exaggerated for effectively explaining the technical contents. The term “and/or” includes one or more combinations defined by associated components.

It will be understood that, although the terms first, second, etc. may be used herein to describe various components, these components should not be limited by these terms. These terms are only used to distinguish one component from another component. For example, a first component could be termed a second component, and vice versa without departing from the scope of the present invention. Unless the context clearly indicates otherwise, the singular forms are intended to include the plural forms as well.

In addition, the terms “beneath”, “lower”, “above”, “upper”, and the like are used herein to describe one component's relationship to other component(s) illustrated in the drawings. The relative terms are intended to encompass different orientations in addition to the orientation depicted in the drawings.

It should be understood that the terms “comprise”, “include”, “have”, and the like are used to specify the presence of stated features, integers, steps, operations, components, elements, or combinations thereof, but do not preclude the presence or addition of one or more other features, integers, steps, operations, components, elements, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

With reference to the accompanying drawings, the following will describe a display panel and a method of fabricating the same according to the invention.

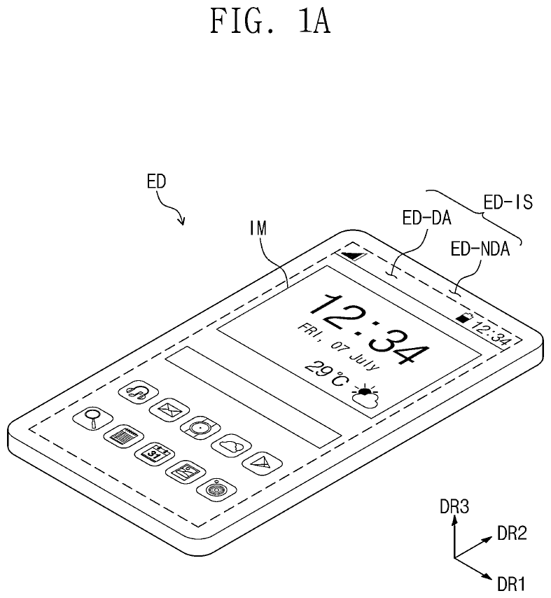

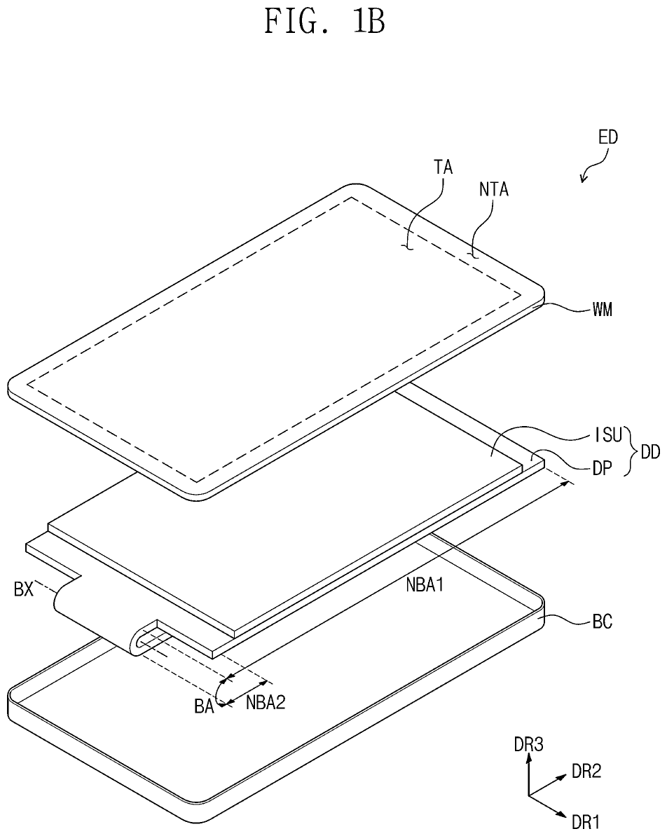

FIG. 1A illustrates a perspective view showing an embodiment of an electronic device according to the invention. FIG. 1B illustrates an exploded perspective view showing an embodiment of an electronic device according to the invention.

In this disclosure, a mobile phone terminal is illustrated in an embodiment of an electronic device ED. The display device DD according to the invention may be applicable not only to large-sized electronic devices such as television sets and monitors, but to relatively small and middle-sized electronic devices such as tablet computers, automotive navigation systems, game consoles, and smart watches.

Referring to FIGS. 1A and 1B, the electronic device ED may display an image IM on a display surface ED-IS. Icons images are illustrated in an embodiment of the image IM. The display surface ED-IS may be parallel to a plane defined by a first direction DR1 and a second direction DR2. A normal direction to the display surface ED-IS, or a thickness direction of the electronic device ED, may be parallel to a third direction DR3.

The display surface ED-IS includes a display region ED-DA on which the image IM is displayed and a non-display region ED-NDA adjacent to the display region ED-DA. The non-display region ED-NDA may be a zone on which no image is displayed. The disclosure, however, is not limited thereto, and the non-display region ED-NDA may be adjacent to one side of the display region ED-DA or may be omitted.

In this disclosure, the phrase “in a plan view” may mean “when viewed in the third direction DR3.” The third direction DR3 may be used to distinguish front and rear surfaces (or top and bottom surfaces) of each of layers or units which will be discussed below. The disclosure, however, is not limited thereto, and a combination of the first, second, and third directions DR1, DR2, and DR3 may be changed into other combination.

The electronic device ED may include a window WM, a display device DD, and an accommodation member BC. Although not shown, the electronic device ED may further include an optic member disposed between the window WM and the display device DD. The optic member may include a polarizer.

The window WM may be disposed on an upper portion of the display device DD, and may externally transmit an image provided from the display device DD. The window WM may include a transmission region TA and a non-transmission region NTA. The transmission region TA may overlap the display region ED-DA, and may have a shape that corresponds to that of the display region ED-DA. The window WM may include a base layer and functional layers disposed on the base layer. The functional layers may include a protective layer and an antifingerprint layer. The base layer of the window WM may include or consist of glass, sapphire, or plastic.

The non-transmission region NTA may overlap the non-display region ED-NDA, and may have a shape that corresponds to that of the non-display region ED-NDA. The non-transmission region NTA may be a zone whose optical transmittance is relatively less than that of the transmission region TA. The base layer of the window WM may include one region defined as the non-transmission region NTA where a bezel pattern is disposed, and may also include another region defined as the transmission region TA where no bezel pattern is disposed. The technical concepts of the invention, however, are not limited thereto, and the non-transmission region NTA may be omitted.

The display device DD may include a display panel DP and an input sensor ISU. In an embodiment of the disclosure, the display panel DP may be one of a liquid crystal display panel, an electrophoretic display panel, microelectromechanical system (“MEMS”) display panel, an electrowetting display panel, an organic light-emitting display panel, an inorganic light-emitting display panel, and a quantum-dot light-emitting display panel, but the invention is not especially limited thereto. The following will describe an embodiment in which the display panel DP is an organic light-emitting display panel.

The input sensor ISU may include one of a capacitive sensor, an optical sensor, an ultrasonic sensor, and an electromagnetic induction sensor. A series of processes may be employed to form the input sensor ISU on the display panel DP, or an individual process may be performed to manufacture the input sensor ISU and then an adhesive layer may be used to attach the input sensor ISU to an upper side of the display panel DP, but the invention is not limited to an illustrative embodiment.

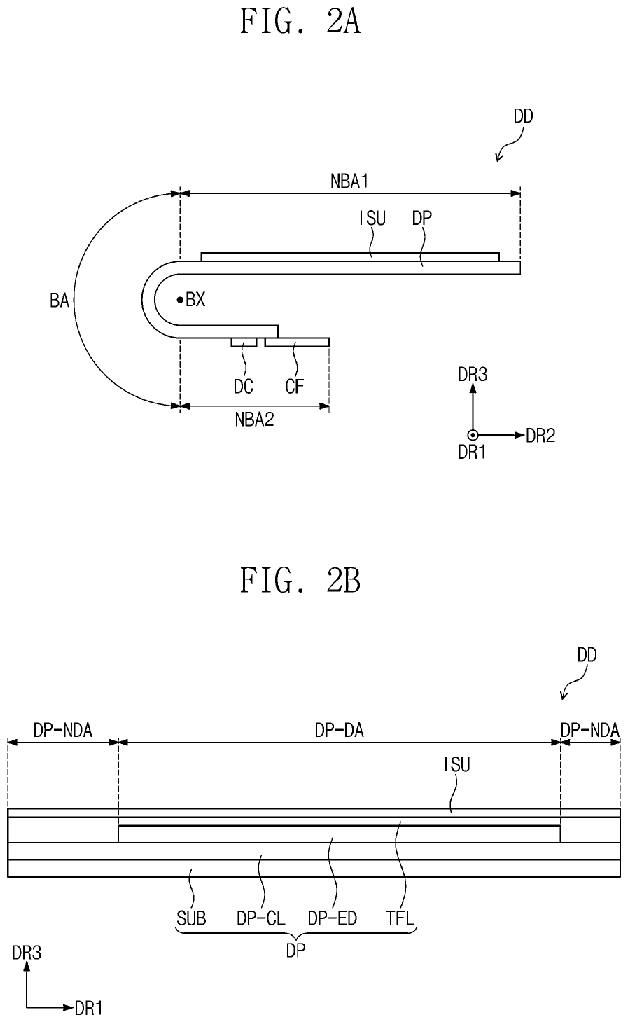

FIGS. 2A and 2B illustrate cross-sectional views showing an embodiment of a display device according to the invention.

Referring to FIG. 2A, the display device DD in an embodiment may include a driver chip DC and a circuit board CF. It is illustrated an embodiment in which the driver chip DC is disposed (e.g., mounted) on the display panel DP, but the disclosure is not limited thereto. In response to control signals transferred from the circuit board CF, the driver chip DC may generate driving signals desired for operations of the display panel DP.

The circuit board CF electrically bonded to the display panel DP may bend to reside on a rear surface of the display panel DP. The accommodation member BC may receive the display device DD and may be coupled to the window WM. The circuit board CF may be disposed on an end of a base substrate SUB and may be electrically connected to a circuit element layer DP-CL. Although not shown, the electronic device Ed may further include a mainboard may further include electronic modules, a camera module, and a power source module that are disposed (e.g., mounted) on the mainboard.

The display panel DP in an embodiment may include a bending region BA, and may also include a first non-bending region NBA1 and a second non-bending region NBA2 that are spaced apart in the second direction DR2 from each other across the bending region BA.

The bending region BA may be defined to indicate a zone where the display panel DP bends along an imaginary bending axis BX that extends in the first direction DR1. The first non-bending region NBA1 may be defined to indicate a zone that overlaps the transmission region (refer to TA of FIG. 1B), and the second bending region NBA2 may be defined to indicate a zone to which the circuit board CF is connected.

When the bending region BA bends along the bending axis BX, the circuit board CF and the driver chip DC may bend in a direction toward the rear surface of the display panel DP to reside on the rear surface of the display panel DP. When the bending region BA bends along the bending axis BX, the first non-bending region NBA1 and the second non-bending region NBA2 may be spaced apart from each other in the third direction DR3.

Although not shown, the bending region BA may cause the occurrence of step difference between the circuit board CF and the rear surface of the display panel DP, and additional component may be disposed to compensate the step difference.

In an embodiment of the disclosure, a width in the first direction DR1 of the first non-bending region NBA1 may be greater than a width in the first direction DR1 of each of the bending region BA and the second non-bending region NBA2. The disclosure, however, is not limited thereto, and the width in the first direction DR1 of the bending region BA may decrease in a direction from the first non-bending region NBA1 toward the second non-bending region NBA2, but the invention is not limited to an illustrative embodiment.

Referring to FIG. 2B, the display panel DP may include a base substrate SUB, a circuit element layer DP-CL, a display element layer DP-ED, and an upper dielectric layer TFL. The input sensor ISU may be disposed on the upper dielectric layer TFL.

FIG. 2B omits regions that correspond to the bending region BA and the second non-bending region NBA2 of the display panel DP discussed above in FIG. 2A.

The display panel DP includes a display region DP-DA and a non-display region DP-NDA. The display region DP-DA of the display panel DP may correspond to the display region ED-DA illustrated in FIG. 1A or the transmission region TA illustrated in FIG. 1B, and the non-display region DP-NDA of the display panel DP may correspond to the non-display region ED-NDA illustrated in FIG. 1A or the non-transmission region NTA illustrated in FIG. 1B.

The base substrate SUB may include at least one plastic film. The base substrate SUB may include a flexible substrate, e.g., a plastic substrate, a glass substrate, a metal substrate, or an organic/inorganic composite material substrate.

The display element layer DP-ED includes a plurality of organic light-emitting diodes. The display element layer DP-ED may further include an organic layer such as a pixel definition layer. The upper dielectric layer TFL may encapsulate the display element layer DP-ED. In an embodiment, the upper dielectric layer TFL may be a thin encapsulation layer, for example. The thin encapsulation layer may include a stack structure in which an inorganic layer, an organic layer, and an inorganic layer are stacked. The upper dielectric layer TFL may protect the display element layer DP-ED against foreign substances such as moisture, oxygen, and dust particles. The disclosure, however, is not limited thereto, and the upper dielectric layer TFL may further include an additional dielectric layer in addition to the thin encapsulation layer. In an embodiment, the upper dielectric layer TFL may further include an optical dielectric layer for control a refractive index, for example.

In an embodiment of the invention, the upper dielectric layer TFL may be replaced with an encapsulation substrate. In this case, the encapsulation substrate may be disposed on the display element layer DP-ED to stand opposite to the base substrate SUB, and may be more rigid than the upper dielectric layer TFL. The encapsulation substrate may seal the display element layer DP-ED and simultaneously protect the display element layer DP-ED against external impact.

The input sensor ISU may be directly disposed on the display panel DP. In this disclosure, the phrase “A is directly disposed on B” means that no adhesive layer is disposed between A and B. In the illustrated embodiment, the input sensor ISU and the display panel DP may be manufactured in a series of processes. The technical concepts of the invention, however, are not limited thereto, and the input sensor ISU may be provided in the form of an individual panel to be coupled through an adhesive layer to the display panel DP. In another embodiment, the input sensor ISU may be omitted.

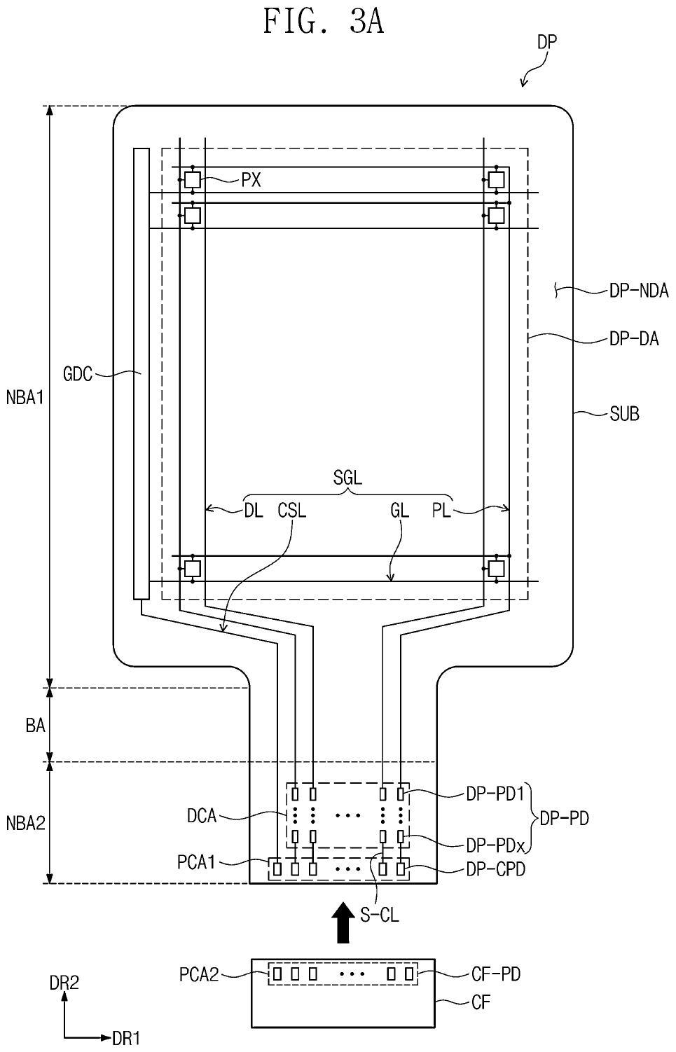

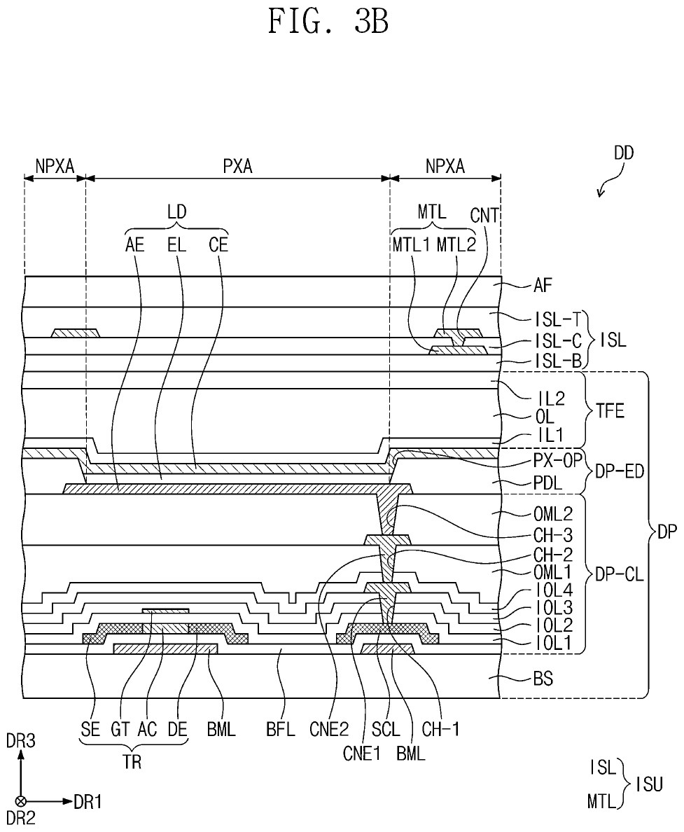

FIG. 3A illustrates a plan view showing an embodiment of a display panel according to the invention. FIG. 3B illustrates a cross-sectional view showing an embodiment of a display module according to the inventive concept.

Referring to FIG. 3A, the display panel DP may include a plurality of pixels PX, a gate driver circuit GDC, a plurality of signal lines SGL, a plurality of display pads DP-PD and DP-CPD.

The pixels PX may be disposed on the display region DP-DA. Each of the pixels PX may include an organic light-emitting diode and a pixel driver circuit connected to the organic light-emitting diode. The display region DP-DA may be a zone where an organic light-emitting diode is substantially disposed. Thus, the pixel driver circuit may be disposed on the display region DP-DA or the non-display region DP-NDA. As long as being electrically connected to the organic light-emitting diode, the pixel driver circuit may be disposed on various positions and the invention is not limited to an illustrative embodiment.

The gate driver circuit GDC may sequentially output gate signals to a plurality of gate lines GL. The gate driver circuit GDC may include a plurality of thin-film transistors formed by, e.g., one of a low temperature polycrystalline silicon (“LTPS”) process and a low temperature polycrystalline oxide (“LTPO”) process each of which is the same as that used to form a driver circuit for the pixels PX. The display panel DP may further include a different driver circuit that provides the pixels PX with emission control signals.

In the illustrated embodiment, it is illustrated that the gate driver circuit GDC is disposed on the non-display region DP-NDA, but the disclosure is not limited thereto. In an embodiment, at least a portion of the gate driver circuit GDC may be disposed overlapping the display region DP-DA in a plan view, for example. In addition, in the illustrated embodiment, it is illustrated that a single gate driver circuit GDC is disposed, but the gate driver circuit GDC may be provided in plural. As long as being electrically connected to the pixels PX, the gate driver circuit GDC may be disposed on various positions and the number of the gate driver circuit GDC may be variously changed, but the invention is not limited to an illustrative embodiment.

The signal lines SGL may include gate lines GL, data lines DL, a power line PL, and a control signal line CSL. The gate lines GL may be connected to corresponding ones of the pixels PX, and the data lines DL may be connected to corresponding ones of the pixels PX. The power line PL may be connected to the pixels PX. The control signal line CSL may provide a scan driver circuit with control signals.

The signal lines SGL may overlap the display region DP-DA and the non-display region DP-NDA.

The display panel DP may include display pads. The display pads may include first display pads DP-PD and second display pads DP-CPD. In an embodiment of the disclosure, the first display pads DP-PD and the second display pads DP-CPD may be disposed on the second non-bending region NBA2.

The non-display region DP-NDA may include a chip region DCA and a first pad region PCA1 that are spaced apart from each other. The chip region DCA may be a zone which is coupled to the driver chip (refer to DC of FIG. 2A) and on which the first display pads DP-PD are disposed, and the first pad region PCA1 may be a zone which is connected to the circuit board CF and on which the second display pads DP-CPD are disposed. The first display pads DP-PD may be electrically connected to the driver chip (refer to DC of FIG. 2A), and may provide the signal lines SGL with electrical signals received from the driver chip DC.

The first display pads DP-PD may include first row display pads DP-PD1 arranged along the first direction DR1, and may also include second to x^{th} row display pads DP-PD2 to DP-PDx (where, x is a natural number equal to or greater than 2) arranged along the first direction DRI and sequentially spaced apart at a predetermined interval in the second direction DR2 from the first row display pads DP-PD1.

The second display pads DP-CPD may be disposed on the first pad region PCA1. The second display pads DP-CPD may be arranged along the first direction DR1. The first display pads DP-PD may be connected through bridge signal lines S-CL to corresponding ones of the second display pads DP-CPD.

Likewise the first display pads DP-PD, the second display pads DP-CPD may include row display pads arranged along the first direction DR1.

The circuit board CF may include circuit pads CF-PD arranged along the first direction DR1. The circuit pads CF-PD may be disposed on a second pad region PCA2 defined on the circuit board CF. The circuit pads CF-PD may be coupled to the display panel DP.

In addition, when the second display pads DP-CPD are disposed in the form of row pads disposed in the first direction DR1, the circuit pads CF-PD included in the circuit board CF may also have an arrangement shape where the circuit pads CF-PD are disposed corresponding to the second display pads DP-CPD, but the invention is not limited to an illustrative embodiment.

The second pad region PCA2 of the circuit board CF may be disposed on the first pad region PCA1. The second display pads DP-CPD may be electrically connected to the circuit pads CF-PD included in the circuit board CF to provide the first display pads DP-PD with electrical signals received from the circuit board CF. The circuit board CF may be rigid or flexible. In an embodiment, when the circuit board CF is flexible, a flexible printed circuit board may be provided as the circuit board CF, for example.

The circuit board CF may include a timing control circuit that controls an operation of the display panel DP. The timing control circuit may be provided in the form of an integrated chip disposed (e.g., mounted) on the circuit board CF. In addition, although not shown, the circuit board CF may include an input sensing circuit that controls the input sensor ISU.

It is described that the display panel DP includes the first display pads DP-PD for mounting the driver chip DC shown in FIG. 2A, but the disclosure is not limited thereto. The driver chip (refer to DC of FIG. 2A) may be disposed (e.g., mounted) on the circuit board CF, and in this case, the first display pads DP-PD may be omitted.

FIG. 3B depicts by way of example a cross-section of the display device DD including one pixel (refer to PX of FIG. 3A) shown in FIG. 3A. The display device DD may include a display panel DP and an input sensor (refer to ISU of FIG. 2B), and the display panel DP may include a base layer BS, a circuit element layer DP-CL, a display element layer DP-ED, and an encapsulation layer TFE. A predetermined pixel (refer to PX of FIG. 3A) may include an equivalent circuit including a plurality of transistors, one capacitor, and an emission element, and an equivalent circuit diagram of the pixel PX may be changed into various shapes. FIG. 3B depicts by way of example one transistor TR and an emission element LD included in the pixel (refer to PX of FIG. 3A).

The display panel DP in an embodiment may include a plurality of dielectric layers, a transistor, a conductive pattern, and a signal line.

A coating process and a deposition process may be employed to form a plurality of inorganic layers, a plurality of organic layers, a semiconductor layer, and a conductive layer. Afterwards, a photolithography process may be used to selectively pattern the inorganic layers, organic layers, the semiconductor layer, and the conductive layer. These processes may form a circuit element layer DP-CL including a plurality of dielectric layers formed from the inorganic and organic layers, a transistor including a semiconductor pattern formed from the semiconductor layer, and a conductive pattern and a signal line that are formed from the conductive layer.

After that, the display element layer DP-ED may be formed which includes the emission element LD including the conductive pattern on the circuit element layer DP-CL, and the encapsulation layer TFE may be formed to cover the display element layer DP-ED.

Referring to FIG. 3B, the circuit element layer DP-CL may include a shield electrode BML, a buffer layer BFL, a plurality of dielectric layers IOL1, IOL2, IOL3, and IOL4 each including an inorganic layer, a plurality of dielectric layers OML1 and OML2 each including an organic layer, a transistor TR, connection electrodes CNE1 and CNE2, and a signal line SCL.

The shield electrode BML may be disposed on the base layer BS. The shield electrode BML may overlap the transistor TR. In addition, in an embodiment, the shield electrode BML may be disposed below the signal line SCL. The shield electrode BML may shield light incident on the transistor TR or the signal line SCL from a lower portion of the display panel DP to protect the semiconductor pattern or a conductive pattern such as the transistor TR and the signal line SCL. The shield electrode BML may include a conductive material. In an embodiment, the shield electrode BML may be connected to the power line (refer to PL of FIG. 3A) to receive a voltage. When a voltage is applied to the shield electrode BML, the transistor TR disposed on the shield electrode BML may maintain a threshold voltage thereof. The disclosure is not limited thereto, and the shield electrode BML may be a floating electrode. In an embodiment, the shield electrode BML may be omitted.

The buffer layer BFL may be disposed on the base layer BS to cover the shield electrode BML. The buffer layer BFL may increase a bonding force between the base layer BS and one of a semiconductor pattern and a conductive pattern disposed on the buffer layer BFL. In addition, the buffer layer BFL may prevent metal elements or impurities from diffusing from the base layer BS toward the semiconductor pattern or the conductive pattern.

The buffer layer BFL may be an inorganic layer. The buffer layer BFL may include at least one selected from silicon oxide, silicon nitride, and silicon oxynitride. In an embodiment, the buffer layer BFL may include a structure in which a silicon oxide layer and a silicon nitride layer are alternately stacked, for example.

The transistor TR may include a source SE, a channel AC, a drain DE, and a gate GT. The source SE, the channel AC, and the drain DE of the transistor TR may be formed from a semiconductor pattern. In cross-section, the source SE and the drain DE may extend in opposite directions from the channel AC. In addition, FIG. 3B depicts a portion of the signal line SCL formed from the semiconductor pattern. Although not shown separately, In a plan view, the signal line SCL may be electrically connected to the drain DE of the transistor TR.

A semiconductor pattern of the transistor TR may include polysilicon, amorphous silicon, or metal oxide, and as long as having semiconductor properties, the semiconductor pattern is not limited to a predetermined one of polysilicon, amorphous silicon, or metal oxide.

The semiconductor pattern may include a plurality of sections that are distinguished based on magnitude of conductivity. A relatively high conductivity may be given to a section of the semiconductor pattern where impurities are doped or metal oxide is reduced, and the section may substantially serve as a source or drain electrode of the transistor TR. The high-conductivity region of the semiconductor pattern may correspond to the source SE and the drain DE of the transistor TR. A lower conductivity may be given to a section of the semiconductor pattern where impurities are not or lightly doped or metal oxide is not reduced, and the section may correspond to the channel AC (or active) of the transistor TR.

A first dielectric layer IOL1 may be disposed on the buffer layer BFL while covering the semiconductor pattern of the transistor TR. The gate GT of the transistor TR may be disposed on the first dielectric layer IOL1. The gate GT may cover the channel AC of the transistor TR. In an embodiment, the gate GT may serve as a mask in a process that dopes the semiconductor pattern of the transistor TR.

The gate GT may include one or more of titanium (Ti), silver (Ag), a silver-containing alloy, molybdenum (Mo), a molybdenum-containing alloy, aluminum (Al), a aluminum-containing alloy, aluminum nitride (AlN), tungsten (W), tungsten nitride (“WN”), copper (Cu), indium tin oxide (“ITO”), and indium zinc oxide (“IZO”), but the invention is not particularly limited thereto.

The first dielectric layer IOL1 may include an inorganic layer. The first dielectric layer IOL1 may be referred to as a first inorganic layer. In an embodiment, the first dielectric layer IOL1 may be an inorganic layer including at least one selected from aluminum oxide, titanium oxide, silicon oxide, silicon nitride, silicon oxynitride, zirconium oxide, and hafnium oxide, for example. The first dielectric layer IOL1 may have a single-layered or multi-layered structure. The first dielectric layer IOL1 may have a structure in which a plurality of inorganic layers are stacked. When the first dielectric layer IOL1 has a structure in which a plurality of layers are stacked, the first dielectric layer IOL1 may further include a buffer inorganic layer that is directly disposed below an inorganic layer and that has a relatively higher amount of oxygen than that of oxygen included in a neighboring inorganic layer. The buffer inorganic layer may have physical properties similar to those of a buffer dielectric layer of the input sensor ISU discussed above.

In addition, in an embodiment, the first dielectric layer IOL1 may further include an organic layer in addition to the inorganic layer. When the first dielectric layer IOL1 has a structure in which an organic layer and an organic layer are stacked, the first dielectric layer IOL1 may further include a buffer inorganic layer disposed between the inorganic layer and the organic layer. In this case, the buffer inorganic layer may also have physical properties similar to those of a buffer dielectric layer of the input sensor ISU discussed above. In an embodiment, in comparison with a neighboring inorganic layer, the buffer inorganic layer may include oxygen (O) and carbon (C) whose amounts are relatively high, for example.

The multi-layered structure of the first dielectric layer IOL1 may be introduced to second, third, and fourth dielectric layers IOL2, IOL3, and IOL4 which will be discussed below. Therefore, the stack structure of the dielectric layer having the multi-layered structure and the configuration of the inorganic layer in the multi-layered structure may be identically applicable to the second, third, and fourth dielectric layers IOL2, IOL3, and IOL4.

The second dielectric layer IOL2 may be disposed on the first dielectric layer IOL1 to cover the gate GT. The second dielectric layer IOL2 may overlap in common the pixels (refer to PX of FIG. 3A). The second dielectric layer IOL2 may include an inorganic layer. The second dielectric layer IOL2 may be referred to as a second inorganic layer. In an embodiment, the second dielectric layer IOL2 may include at least one selected from silicon oxide, silicon nitride, and silicon oxynitride, for example. The second dielectric layer IOL2 may be an inorganic layer and/or an organic layer, and may have a single-layered or multi-layered structure. In an embodiment, the second dielectric layer IOL2 may have a multi-layered structure including a silicon oxide layer and a silicon nitride layer.

The third dielectric layer IOL3 may be disposed on the second dielectric layer IOL2. The third dielectric layer IOL3 may include an inorganic layer. The third dielectric layer IOL3 may be referred to as a third inorganic layer. The third dielectric layer IOL3 may have a single-layered or multi-layered structure. In an embodiment, the third dielectric layer IOL3 may have a multi-layered structure including a silicon oxide layer and a silicon nitride layer, for example.

A first connection electrode CNE1 may be disposed on the third dielectric layer IOL3. The first connection electrode CNE1 may be coupled to the signal line SCL through a first contact hole CH-1 that penetrates the first, second, and third dielectric layers IOL1, IOL2, and IOL3.

A fourth dielectric layer IOL4 may be disposed on the third dielectric layer IOL3. The fourth dielectric layer IOL4 may include an inorganic layer and may be referred to as a fourth inorganic layer. The fourth dielectric layer IOL4 may include a silicon oxide layer.

A fifth dielectric layer OML1 may be disposed on the fourth dielectric layer IOL4. The fifth dielectric layer OML1 may include an organic layer. The fifth dielectric layer OML1 may be referred to as a first organic layer. The first organic layer may include at least one selected from acryl-based resin, methacryl-based resin, polyisoprene, vinyl-based resin, epoxy-based resin, urethane-based resin, cellulose-based resin, siloxane-based resin, polyamide-based resin, and perylene-based resin.

A second connection electrode CNE2 may be disposed on the fifth dielectric layer OML1. The second connection electrode CNE2 may be coupled to the first connection electrode CNE1 through a second contact hole CH-2 that penetrates the fourth dielectric layer IOL4 and the fifth dielectric layer OML1.

A sixth dielectric layer OML2 may be disposed on the fifth dielectric layer OML1 to cover the second connection electrode CNE2. The sixth dielectric layer OML2 may include an organic layer. The sixth dielectric layer OML2 may be referred to as a second organic layer. The second organic layer may include at least one selected from acryl-based resin, methacryl-based resin, polyisoprene, vinyl-based resin, epoxy-based resin, urethane-based resin, cellulose-based resin, siloxane-based resin, polyamide-based resin, and perylene-based resin.

Although not shown in FIG. 3B, the circuit element layer DP-CL may further include a plurality of transistors, and may also further include signal lines electrically connected to the plurality of transistors. The signal lines may extend to have a connection with the first display pads DP-PD of the non-display region (refer to DP-NDA of FIG. 3A). In addition, the signal lines may be connected to sensing pads.

The display element layer DP-ED may be disposed on the circuit element layer DP-CL. The display element layer DP-ED may include a pixel definition layer PDL and an emission element LD. The emission element LD may include a first electrode AE, an emission layer EL, and a second electrode CE.

The first electrode AE may be disposed on the sixth dielectric layer OML2. The first electrode AE may be connected to the second connection electrode CNE2 through a third contact hole CH-3 that penetrates the sixth dielectric layer OML2. The first electrode AE may be electrically connected through the first and second connection electrodes CNE1 and CNE2 to the drain DE of the transistor TR.

The first electrode AE may be referred to as a pixel electrode. The first electrode AE may include or consist of a metallic material, a metal alloy, or a conductive compound. The first electrode AE may be an anode or a cathode. The first electrode AE may be a transmissive electrode, a transflective electrode, or a reflective electrode. When the first electrode AE is a transmissive electrode, the first electrode AE may include transparent metal oxide, such as ITO, IZO, zinc oxide (ZnO), or indium tin zinc oxide (“ITZO”). When the first electrode AE is a transflective or reflective electrode, the first electrode AE may include Ag, Mg, Cu, Al, Pt, Pd, Au, Ni, Nd, Ir, Cr, Li, Ca, LiF/Ca, LiF/Al, Mo, Ti, W, or any compound or combination thereof (e.g., a combination of Ag and Mg).

In an alternative embodiment, the first electrode AE may be a multi-layered structure including a reflective or transflective layer including or consisting of the material mentioned above and a transparent conductive layer including or consisting of ITO, IZO, zinc oxide (ZnO), or ITZO. In an embodiment, the first electrode AE may have a tri-layered structure of ITO/Ag/ITO, for example, but the disclosure is not limited thereto. In another embodiment, the first electrode AE may include the metallic material discussed above, any combination of two or more selected from the metallic materials discussed above, or any oxide of the metallic materials discussed above, but the disclosure is not limited thereto.

The pixel definition layer PDL may be disposed on the sixth dielectric layer OML2. In an embodiment, the pixel definition layer PDL may include or consist of polymer resin. In an embodiment, the pixel definition layer PDL may include or consist of polyacrylate-based resin or polyimide-based resin, for example. In addition, the pixel definition layer PDL may include or consist of an inorganic material in addition to the polymer resin. The pixel definition layer PDL may include or consist of a light-absorbing material, a black pigment, or a black dye. The pixel definition layer PDL including or consisting of black pigment or black dye may define a black pixel definition layer. When the pixel definition layer PDL is formed, a carbon black may be used as black pigment or black dye, but the disclosure is not limited thereto. The pixel definition layer PDL may include or consist of an inorganic material. In an embodiment, the pixel definition layer PDL may include or consist of silicon nitride, silicon oxide, or silicon oxynitride, for example.

The pixel definition layer PDL may define a pixel opening PX-OP that exposes at least a portion of the first electrode AE. In the display device DD in an embodiment, the pixel definition layer PDL may distinguish emission regions PXA which will be discussed below. The display device DD may include emission regions PXA and non-emission regions NPXA, and the non-emission region NPXA may overlap the pixel definition layer PDL. A section that corresponds to the first electrode AE exposed by the pixel opening PX-OP may be defined as the emission region PXA.

In the emission element LD, the emission layer EL may be disposed on the first electrode AE. In the illustrated embodiment, the emission layer EL may emit light having at least one selected from blue, red, and green colors. In an embodiment, in an entirety of the display region (refer to DP-DA of FIG. 3A), the emission layer EL may provide blue light.

The second electrode CE may be disposed on the emission layer EL. The second electrode CE may have a single unitary shape, and may be disposed in common on the plurality of pixels (refer to PX of FIG. 3A). The second electrode CE may be referred to as a common electrode. The second electrode CE may be a cathode or an anode. In an embodiment, when the first electrode AE is an anode, the second electrode CE may be a cathode, and when the first electrode AE is a cathode, the second electrode CE may be an anode, for example.

The second electrode CE may be a transmissive electrode, a transflective electrode, or a reflective electrode. When the second electrode CE is a transmissive electrode, the second electrode CE may include or consist of transparent metal oxide, such as ITO, IZO, zinc oxide (ZnO), or ITZO. In addition, the second electrode CE may a include Ag, Mg, Cu, Al, Pt, Pd, Au, Ni, Nd, Ir, Cr, Li, Ca, LiF/Ca, LiF/Al, Mo, Ti, W, or any compound or combination thereof (e.g., a combination of Ag and Mg).

Although not shown, a hole control layer may be disposed between the first electrode AE and the emission layer EL. The hole control layer may include a hole transport layer and may further include a hole injection layer. An electron control layer may be disposed between the emission layer EL and the second electrode CE. The electron control layer may include an electron transport layer and may further include an electron injection layer. An open mask may be used such that the hole control layer and the electron control layer may be formed in common on the plurality of pixels (refer to PX of FIG. 3A).

An encapsulation layer TFE may be disposed on the display element layer DP-ED. The encapsulation layer TFE may include a first inorganic layer IL1, an organic layer OL, and a second inorganic layer IL2 that are sequentially stacked. However, the layers included in the encapsulation layer TFE are not limited thereto.

The inorganic layers IL1 and IL2 may protect the display element layer DP-ED against moisture and oxygen, and the organic layer OL may protect the display element layer DP-ED against foreign substances such as dust particles. The inorganic layers IL1 and IL2 may include at least one selected from silicon nitride, silicon oxynitride, silicon oxide, titanium oxide, and aluminum oxide. The organic layer OL may include an acrylic organic material. However, the kind of materials included in the inorganic layers IL1 and IL2 and the organic layer OL is not limited thereto.

An input sensor ISU may be disposed on the encapsulation layer TFE. The input sensor ISU may be referred to as a sensor layer, an input sensing layer, or an input sensing panel. The input sensor ISU may include a plurality of sensor dielectric layers ISL and a plurality of sensor conductive layers MTL. One sensor dielectric layer (e.g., ISL-B) of the plurality of sensor dielectric layers ISL may be directly disposed on the display panel DP. In an embodiment, the input sensor ISU may include a first sensor dielectric layer ISL-B, a first sensor conductive layer MTL1, a second sensor dielectric layer ISL-C, a second sensor conductive layer MTL2, and a third sensor dielectric layer ISL-T that are sequentially stacked in the third direction DR3 on the display panel DP, for example.

The first sensor dielectric layer ISL-B may include a base dielectric layer. In addition, the first sensor dielectric layer ISL-B may include a buffer dielectric layer. In an embodiment, the input sensor ISU may be a single layer including or consisting of only a base dielectric layer or only a buffer dielectric layer, or may be a stack structure including a buffer dielectric layer or a base dielectric layer, for example, but the invention is not limited to an illustrative embodiment.

The first sensor conductive layer MTL1 and the second sensor conductive layer MTL2 may each have a multi-layered structure. The multi-layered sensor conductive layer may have a structure in which two or more transparent layers and/or two or more metal layers are stacked. In an embodiment, the multi-layered sensor conductive layer may have a structure in which a transparent layer and a metal layer are stacked or a structure in which metal layers having different metals are stacked, for example.

The first sensor conductive layer MTL1 and the second sensor conductive layer MTL2 may each include a transparent conductive layer, such as ITO, IZO, zinc oxide (ZnO), ITZO, poly (3,4-ethylenedioxythiophene) (“PEDOT”), metal nano-wire, or graphene. A metal layer included in each of the first sensor conductive layer MTL1 and the second sensor conductive layer MTL2 may include molybdenum, silver, titanium, copper, aluminum, or any alloys thereof.

The first sensor conductive layer MTL1 and the second sensor conductive layer MTL2 may each include sensing electrodes of the input sensor ISU, and may further include sensing lines.

The second sensor dielectric layer ISL-C may be disposed on the first sensor conductive layer MTL1. The third sensor dielectric layer ISL-T may be disposed on the second sensor conductive layer MTL2. The second sensor dielectric layer ISL-C and the third sensor dielectric layer ISL-T may each include an inorganic layer. The second sensor dielectric layer ISL-C and the third sensor dielectric layer ISL-T may include an organic layer.

The first sensor dielectric layer ISL-B, the second sensor dielectric layer ISL-C, and the third sensor dielectric layer ISL-T may each include at least one selected from silicon nitride (SiNx) and silicon oxynitride (SiOxNy). Additionally or alternatively, the first sensor dielectric layer ISL-B, the second sensor dielectric layer ISL-C, and the third sensor dielectric layer ISL-T may each include silicon oxide (SiOx). The first sensor dielectric layer ISL-B, the second sensor dielectric layer ISL-C, and the third sensor dielectric layer ISL-T may each include at least one of inorganic layers, such as an aluminum oxide layer, a titanium oxide layer, a zirconium oxide layer, and a hafnium oxide layer. In silicon nitride (SiNx), silicon oxynitride (SiOxNy), and silicon oxide (SiOx), each of x and y may be greater than zero.

When the first sensor dielectric layer ISL-B, the second sensor dielectric layer ISL-C, and the third sensor dielectric layer ISL-T include an organic layer, the organic layer may include at least one selected from acryl-based resin, methacryl-based resin, polyisoprene-based resin, vinyl-based resin, epoxy-based resin, urethane-based resin, cellulose-based resin, siloxane-based resin, polyimide-based resin, polyamide-based resin, and perylene-based resin.

FIG. 3B depicts that the input sensor ISU includes the first sensor conductive layer MTL1 and the second sensor conductive layer MTL2 which are stacked, but the disclosure is not limited thereto. In an embodiment, the input sensor ISU may include one sensor conductive layer MTL disposed on the first sensor dielectric layer ISL-B, for example. In this case, one of the second and third dielectric layers ISL-C and ISL-T may be omitted.

In FIG. 3B, in order to express a simplified stack structure, each of the first and second sensor conductive layers MTL1 and MTL2 is illustrated as a single unitary layer that overlaps an entirety of the display panel DP, but the disclosure is not limited thereto. Each of the first and second sensor conductive layers MTL1 and MTL2 may be patterned.

In an embodiment, the display device DD may include an optical layer AF. In an embodiment, the optical layer AF may be directly disposed on the third dielectric layer ISL-T. In an alternative embodiment, an adhesive layer may further be included between the optical layer AF and the input sensor ISU, and the invention is not limited to an illustrative embodiment.

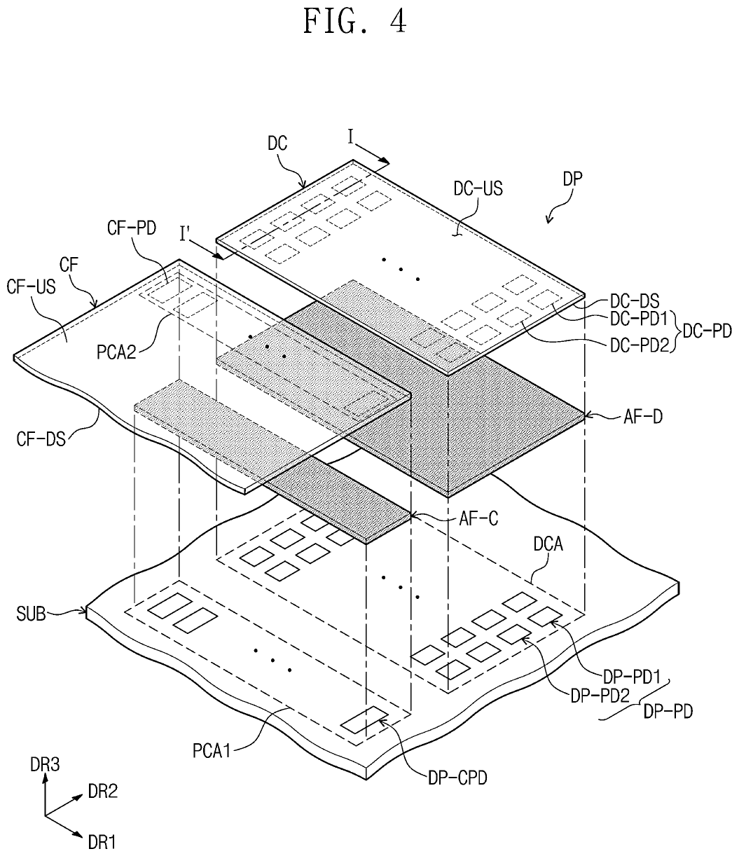

FIG. 4 illustrates an exploded perspective view showing an embodiment of a bonding region of a display device according to the invention.

Referring to FIG. 4, the display panel DP may include a first adhesive layer AF-C disposed between the circuit board CF and the base substrate SUB and a second adhesive layer AF-D disposed between the driver chip DC and the base substrate SUB. The first adhesive layer AF-C may connect the circuit board CF to the display panel DP, and the second adhesive layer AF-D may connect the driver chip DC to the display panel DP. The first adhesive layer AF-C and the second adhesive layer AF-D may each have dielectric properties. The first adhesive layer AF-C and the second adhesive layer AF-D may respectively physically combine the circuit board CF and the driver chip DC with the display panel DP.

The circuit board CF may include a top surface CF-US and a bottom surface CF-DS. The bottom surface CF-DS of the circuit board CF may face the display panel DP. The circuit pads CF-PD may be disposed on the bottom surface CF-DS of the circuit board CF, and may be electrically connected to corresponding second display pads DP-CPD of the display panel DP.

The driver chip DC may include a top surface DC-US and a bottom surface DC-DS. The bottom surface DC-DS of the driver chip DC may face the display panel DP. The driver chip DC may include chip pads DC-PD disposed on the bottom surface DC-DS. The chip pads DC-PD may be electrically connected to corresponding first display pads DP-PD disposed on the base substrate SUB.

The chip pads DC-PD may include first row chip pads DC-PD1 arranged along the first direction DR1, second row chip pads DC-PD2 arranged along the first direction DR1 and spaced apart in the second direction DR2 from the first row chip pads DC-PD1, and nth row chip pads (where, n is a natural number equal to or greater than 3) spaced apart in the second direction DR2 from the second row chip pads DC-PD2. The first row chip pads DC-PD1 and the second row chip pads DC-PD2 may each have a shape that is externally exposed from the bottom surface DC-DS of the driver chip DC.

FIG. 4 depicts that the chip pads DC-PD are disposed in four rows, but the disclosure is not limited thereto, and the chip pads DC-PD may be disposed in five or more rows on the basis of the arrangement of the first display pads DP-PD.

The following will illustrate a bonding between the circuit board CF and the display panel DP, but a subsequently described bonding structure between the circuit board CF and the display panel DP may be identically applicable to a bonding between the driver chip DC and the display panel DP.

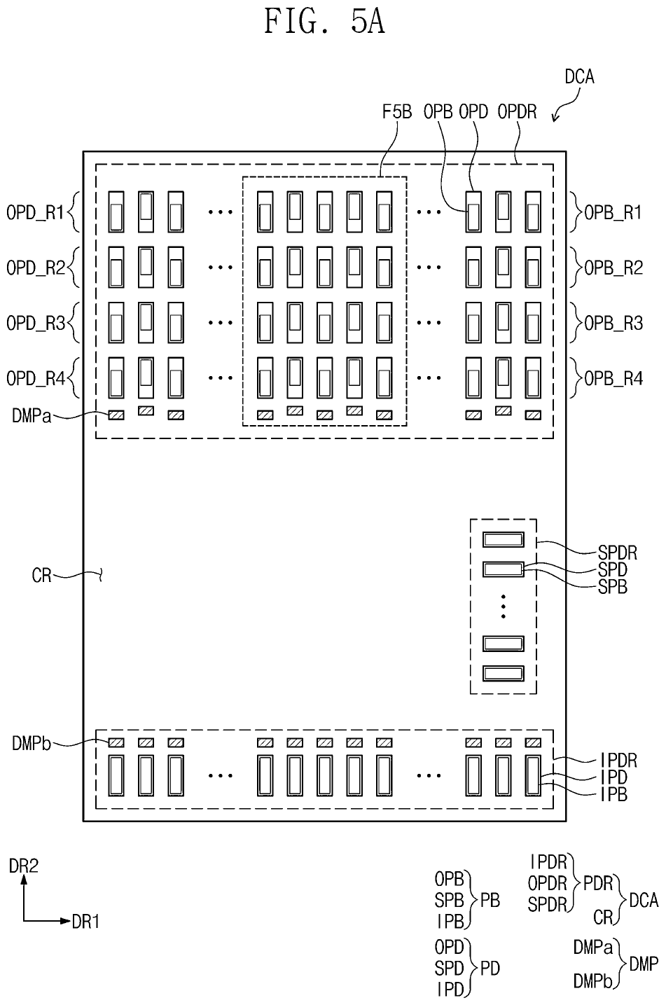

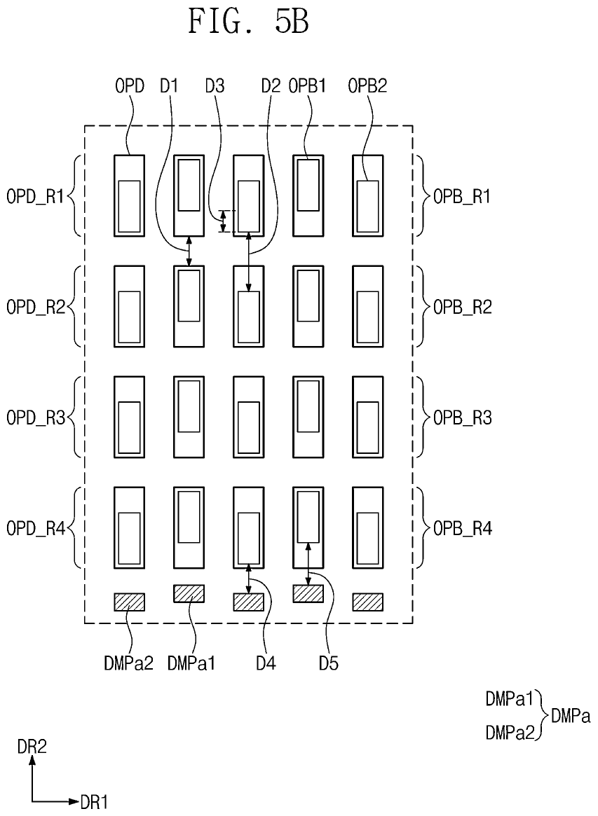

In addition, subsequently described pads (refer to PD of FIG. 5A) may correspond to the first display pads (refer to DP-CPD of FIG. 4), and subsequently described bumps (refer to PB of FIG. 5A) may correspond to the chip pads (refer to DC-PD of FIG. 4).

FIGS. 5A and 5B illustrate plan views showing an embodiment of a chip region of a display device according to the invention. In detail, FIG. 5B is an enlarged view showing a portion of section F5B depicted in FIG. 5A.

Referring to FIG. 5A, the display panel DP may include an input pad region IPDR, a side pad region SPDR, and an output pad region OPDR. Each of the input pad region IPDR, the side pad region SPDR, and the output pad region OPDR may include a plurality of pads PD.

The input pad region IPDR may include a plurality of input pads IPD, and the side pad region SPDR may include a plurality of side pads SPD.

The input pads IPD may be arranged along the first direction DRI to constitute a row. The side pads SPD may be arranged along the second direction DR2 to constitute a column. The input pads IPD may be disposed to allow subsequently described input bumps IPB to correspond to the input pads IPD, and the side pads SPD may be disposed to allow subsequently described side bumps SPB to correspond to the side pads SPD.

The arrangement of the input pads IPD and the side pads SPD is illustrated by way of example and may be variously changed corresponding to a design of the display panel DP or the driver chip DC without being limited to an illustrative embodiment.

The input pad region IPDR and the side pad region SPDR may be provided with various signals provided from an outside of the display device (refer to DD of FIG. 1B). The various signals may be provided to the driver chip DC through a plurality of input bumps IPB disposed corresponding to the input pad region IPDR and through a plurality of side bumps SPB disposed corresponding to the side pad region SPDR.

The output pad region OPDR may include a plurality of output pads OPD. The plurality of output pads OPD may be arranged along the first direction DR1 and the second direction DR2. The plurality of output pads OPD arranged along the first direction DR1 may be defined as output pad rows OPD_R1, OPD_R2, OPD_R3, and OPD_R4. The output pad rows OPD_R1, OPD_R2, OPD_R3, and OPD_R4 may be arranged along the second direction DR2. In an embodiment, the output pads OPD arranged along the first direction DR1 in one output pad row (e.g., OPD_R1) may be also referred to as first row output pads, and the output pads OPD arranged along the first direction DR1 in the next output pad row (e.g., OPD_R2) may be also referred to as second row output pads, for example, but the disclosure is not limited thereto.

Although it is illustrated that the output pad region OPDR includes only four output pad rows OPD_R1, OPD_R2, OPD_R3, and OPD_R4, the output pad region OPDR may include five or more output pad rows, and the invention is not limited to an illustrative embodiment.

The output pad region OPDR may be provided with various signals, which are output from the driver chip (refer to DC of FIG. 4), through a plurality of output bumps OPB disposed to correspond to the output pad region OPDR. The various signals provided to the output pad region OPDR may be provided to the pixels PX, which are disposed on the display region DP-DA, through a plurality of lines connected to the output pad region OPDR.

In correspond to the number of the pixels PX, the output pad region OPDR may include output pads OPD whose number is greater than that of the input pads IPD of the input pad region IPDR and that of the side pads SPD of the side pad region SPDR.

The output pads OPD included in the output pad rows OPD_R1, OPD_R2, OPD_R3, and_R4 may have the same shape and may be disposed side by side. In an embodiment, the output pads OPD disposed in the same row may be aligned along the first direction DR1, for example.

The output bumps OPB disposed corresponding to the output pad region OPDR may be disposed to have predetermined patterns. The output bumps OPB may include output bump rows OPB_R1, OPB_R2, OPB_R3, OPB_R4 in each of which a plurality of output bumps OPB are arranged along the first direction DR1. In an embodiment, the output bumps OPB arranged along the first direction DR1 in one output bump row (e.g., OPB_R1) may be also referred to as first row output bumps, and the output bumps OPB arranged along the first direction DR1 in the next output bump row (e.g., OPB_R2) may be also referred to as second row output bumps, for example, but the disclosure is not limited thereto.

The output bumps OPB included in each of the output bump rows OPB_R1, OPB_R2, OPB_R3, OPB_R4 may have the same shape. The output bumps OPB disposed in the same row may be staggeringly disposed in a zigzag fashion in the first direction DR1. In an embodiment, neighboring output bumps OPB disposed in the same row may be partially staggeringly disposed while being shifted at a predetermined distance in the second direction DR2, for example. In this case, the shifted predetermined distance may be less than a distance between neighboring rows.

The arrangement of the output bumps OPB disposed in a zigzag fashion on the output pads OPD may minimize the occurrence of crack or fracture possibly occurring when the driver chip DC is disposed (e.g., mounted).

The chip region DCA may include a pad region PDR on which are disposed the pads PD of each of the input pad region IPDR, the side pad region SPDR, and the output pad region OPDR, and may also include a circuit region CR on which circuits are disposed. Although it is illustrated that subsequently described dummy patterns DMP are disposed on only the pad region PDR, the dummy pattern DMP may be disposed on only the circuit region CR or on both of the circuit region CR and the pad region PDR, and the invention is not limited to an illustrative embodiment. In an embodiment, the dummy pattern DMP may overlap circuits disposed on the circuit region CR, for example, but the invention is not limited to an illustrative embodiment.

In an embodiment of the disclosure, the dummy pattern DMP may be provided in plural, and ones of dummy patterns DMPa and DMPb may be spaced apart at a predetermined distance from the pads PD of the input pad region IPDR or the pads PD of the output pad region OPDR. In comparison with the pads PD and the bumps PB, the dummy pattern DMP may include a dielectric material.

Referring to FIG. 5B, a plurality of output pads OPD arranged along the first direction DR1 may be defined as an output pad row. In addition, a plurality of output bumps OPB arranged along the first direction DR1 may be defined as an output bump row.

In an embodiment of the disclosure, the output pad rows may be spaced apart at a first distance D1 in the second direction DR2. In an embodiment, the first distance D1 may indicate a distance in the second direction DR2 between the output pads OPD that neighbor in the second direction DR2, for example.

Referring to FIGS. 5A and 5B, the output bump rows OPB_R1, OPB_R2, OPB_R3, OPB_R4 in an embodiment of the disclosure may be spaced apart at a second distance D2 in the second direction DR2. In an embodiment, the second distance D2 may indicate a distance in the second direction DR2 between the output bumps OPB that neighbor in the second direction DR2, for example.

Each of the output bump rows OPB_R1, OPB_R2, OPB_R3, OPB_R4 may include a plurality of first bumps OPB1 and a plurality of second bumps OPB2. The first bumps OPB1 may be aligned in the first direction DR1. The second bumps OPB2 may be aligned in the first direction DR1. The first bumps OPB1 and the second bumps OPB2 may be alternately arranged.

The second bumps OPB2 may be disposed shifted in the second direction DR2 at a third distance D3 from the first bumps OPB1. The third distance D3 may be less than the second distance D2. The second bumps OPB2 may be disposed shifted in the second direction DR2 at the third distance D3 from the first bumps OPB1, and thus the first bumps OPB1 and the second bumps OPB2 may be staggeringly disposed in a zigzag fashion.

When the bumps PB are not disposed in a zigzag fashion, and when the driver chip (refer to DC of FIG. 4) is provided with heat and pressure to electrically connect the pads PD of a pad region to the bumps PB of a bump region, a pressure (or stress) may be concentrated on a region adjacent to the bumps PB in the display panel (refer to DP of FIG. 4) and thus the display panel DP may suffer from deformation or crack. The regions to which the pressure (or stress) is concentrated in a predetermined one direction may be aligned to induce deformation of an entirety of the display panel DP.

In an embodiment of the disclosure, the bumps PB of a bump region may be disposed in a zigzag fashion in the first direction DR1, and thus regions on which a pressure (or stress) is concentrated may not be aligned in a predetermined one direction, with the result that the regions may be uniformly distributed on an entirety of the display panel DP. The display panel DP may thus be prevented from being entirely deformed.

In an embodiment of the disclosure, the bumps PB of different output bump rows may be aligned with each other in the second direction DR2. The first bumps OPB1 of a first output bump row OPB_R1 may be aligned in the second direction DR2 with the first bumps OPB1 of a second output bump row OPB_R2. The second bumps OPB2 of the first output bump row OPB_R1 may be aligned in the second direction DR2 with the second bumps OPB2 of the second output bump row OPB_R2.

The first bumps OPB1 of the second output bump row OPB_R2 may be aligned in the second direction DR2 with the first bumps OPB1 of a third output bump row OPB_R3. The second bumps OPB2 of the second output bump row OPB_R2 may be aligned in the second direction DR2 with the second bumps OPB2 of the bump row OPB_R3. The first bumps OPB1 of the third output bump row OPB_R3 may be aligned in the second direction DR2 with the first bumps OPB1 of a fourth output bump row OPB_R4. The second bumps OPB2 of the third output bump row OPB_R3 may be aligned in the second direction DR2 with the second bumps OPB2 of the fourth output bump row OPB_R4.

A distance in the second direction DR2 between the first bumps OPB1 of neighboring bump rows may be the second distance D2, and likewise a distance in the second direction DR2 between the second bumps OPB2 of neighboring bump rows.

A plurality of bumps PB of the first to fourth output bump rows OPB_R1 to OPB_R4 may be aligned in the second direction DR2 to increase density of the bumps PB and to contrive microminiaturization of the display device DD.

Although it is illustrated that the bumps PB of the first to fourth output bump rows OPB_R1 to OPB_R4 are all aligned in the second direction DR2, only the bumps PB of some bump rows may be aligned in the second direction DR2, and the invention is not limited to an illustrative embodiment.

In an embodiment of the disclosure, the dummy pattern DMP may be spaced apart at a fourth distance D4 from the fourth row bumps PB. Embodiments of the disclosure, however, is not limited thereto, and when fifth row bumps PB are additionally disposed between the dummy pattern DMP and the fourth row bumps PB, a distance between the dummy pattern DMP and the fifth row bumps PB may be the fourth distance D4.

A length in the second direction DR2 of the dummy pattern DMP may be less than a length in the second direction DR2 of the bump PB. In an alternative embodiment, the length in the second direction DR2 of the dummy pattern DMP may be the same as the length in the second direction DR2 of the bump PB, and the invention is not limited to an illustrative embodiment.

In addition, the length in the second direction DR2 of the dummy pattern DMP may be less than the fourth distance D4 and a fifth distance D5. In an alternative embodiment, the length in the second direction DR2 of the dummy pattern DMP may be the same as the fourth distance D4 and the fifth distance D5, and the invention is not limited to an illustrative embodiment.

The dummy pattern DMP may include a plurality of dummy members DMPa1 and DMPa2. The plurality of dummy members DMPa1 and DMPa2 may include first dummy members DMPa1 and second dummy members DMPa2. The first dummy members DMPa1 and the second dummy members DMPa2 may be aligned in the first direction DR1. The first dummy members DMPa1 and the second dummy members DMPa2 may be alternately arranged with each other.

The second dummy members DMPa2 may be disposed shifted in the second direction DR2 at a predetermined distance from the first dummy members DMPa1. As the second dummy members DMPa2 are shifted at a predetermined distance from the first dummy members DMPa1, the first dummy members DMPa1 and the second dummy members DMPa2 may be staggeringly disposed in a zigzag fashion.

The fourth distance D4 may be provided between the second dummy members DMPa2 and first pads PD, and the fifth distance D5 may be provided between the first dummy members DMPa1 and second pads PD. In an embodiment of the disclosure, the fourth distance D4 and the fifth distance D5 may be the same as each other. In an alternative embodiment, the fourth distance D4 and the fifth distance D5 may be different from each other, and the invention is not limited to an illustrative embodiment.

The fourth distance D4 and the fifth distance D5 may be greater than the third distance D3. In an alternative embodiment, the fourth distance D4 and the fifth distance D5 may be same as the third distance D3, and the invention is not limited to an illustrative embodiment.

Although it is illustrated only relationship between a first dummy pattern DMPa and the output pads OPD, the relationship between the first dummy pattern DMPa and the pads PD may also be applicable to that between a second dummy pattern DMPb and the input pads IPD, and the invention is not limited to an illustrative embodiment.

However, detailed numerical values of the dummy pattern DMP, the dummy members DMPa1 and DMPa2, the pads PD, and the bumps PB may be changed depending on design of the display device (refer to DD of FIG. 3B), and each component may have a numerical relationship with respect to a predetermined numerical value of design so as to minimize deformation of the display panel (refer to DP of FIG. 3A), and the invention is not limited to an illustrative embodiment.

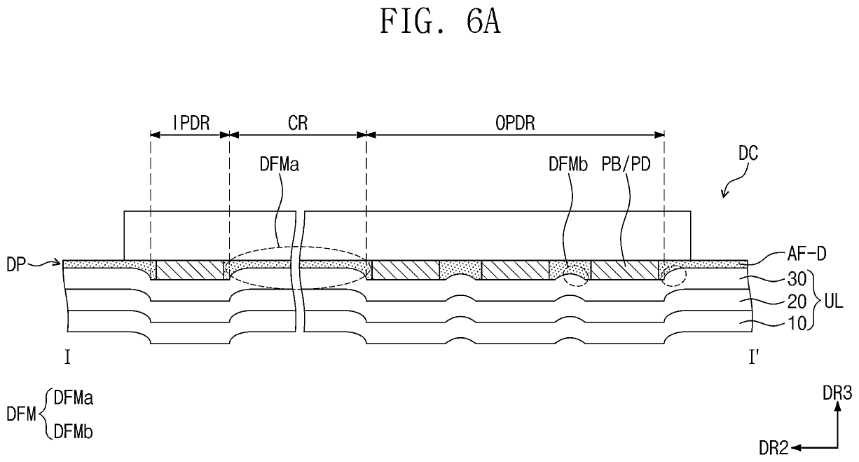

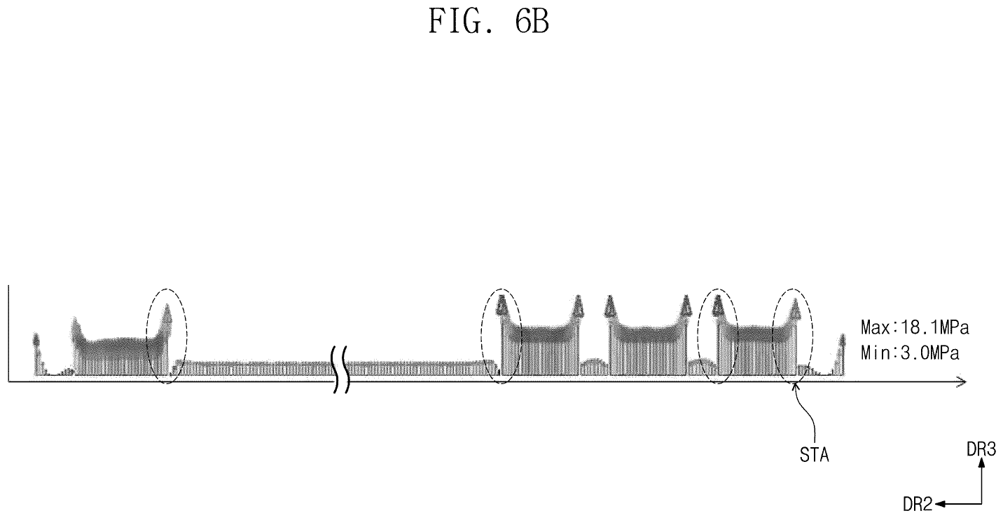

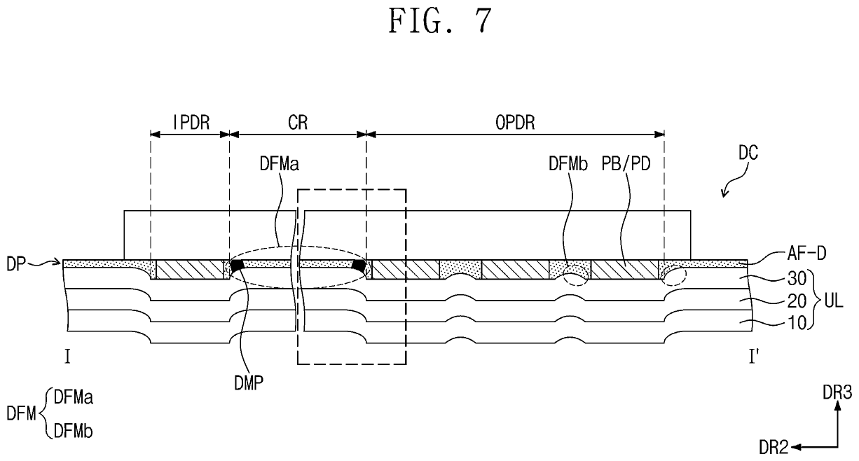

FIG. 6A illustrates a simplified enlarged cross-sectional view showing a comparative example of a chip region of a display device. FIG. 6B illustrates a graph showing a stress applied to a comparative example of a chip region of a display device. FIG. 7 illustrates a simplified enlarged cross-sectional view showing an embodiment of a chip region of a display device according to the invention.

FIGS. 6A and 7 depict simplified some component of a display device, and a configuration of a display device of the disclosure is not limited to that shown in FIG. 7. In detail, FIG. 7 illustrates a simplified view taken along line I-I′ of FIG. 4.

Referring to FIGS. 6A, 6B, and 7, an upper layer UL may include a plurality of layers. The upper layer UL may include a first upper layer 10, a second upper layer 20 disposed on the first upper layer 10, and a third upper layer 30 disposed on the second upper layer 20. The first, second, and third upper layers 10, 20, and 30 may correspond to ones of the circuit element layer DP-CL, the display element layer DP-ED, the encapsulation layer TFE, and the input sensor ISU that are discussed in FIG. 3B, but the invention is not limited to an illustrative embodiment.

The driver chip DC may be provided with heat and pressure to combine the driver chip DC to the display panel DP. The bumps PB of the driver chip DC may pressurize the display panel DP in the third direction DR3. In this case, as the display panel DP is flexible and the driver chip DC is rigid, the flexible display panel DP may be deformed. In an embodiment, some layers of the flexible display panel DP may be pushed or pulled in a direction that intersects the third direction DR3, and an entirety of the display panel DP may suffer from deformation and crack, for example.

As shown in drawing figures, a stress may be concentrated on stress-concentrated regions STA adjacent to positions where the bumps PB contact the display panel DP or the pads PD. The stress-concentrated regions STA may mean an area where stress is relatively concentrated as the display panel DP and the driver chip DC are combined. The stress-concentrated regions STA in the display panel DP may be disposed corresponding to an arrangement of the bumps PB. In accordance with the arrangement of the bumps PB, deformation and crack occurring in the stress-concentrated regions STA may cause an entirety of the display panel DP to suffer from deformation and crack.

Referring together to FIGS. 6A and 6B, a maximum pressure of about 18.1 megapascals (MPa) may be applied to the regions adjacent to the positions where the bumps PB contact the display panel DP or the pads PD, and a minimum pressure of about 3.0 MPa may be applied to other regions. In an embodiment, as the pressure applied to the stress-concentrated region STA is greater than that of other regions, deformation and crack may occur in the stress-concentrated regions STA, and as a plurality of bumps PB pressurize the display panel DP, deformation and crack may occur in an entirety of the display panel DP, for example.

In addition, as the bumps PB are densely disposed in the pad regions IPDR and OPDR, the display panel DP may suffer from deformation only at a predetermined region DFMb, and even though deformation occurs in the predetermined region DFMb, deformation of the display panel DP may be limited. However, no bumps may be disposed on the circuit region CR, and thus when deformation occurs in the display panel DP, the display panel DP on a region DFMa where the deformation occurs may more protrude toward the driver chip DC than the display panel DP on the pad regions IPDR and OPDR.

Referring to the comparative examples shown in FIGS. 6A and 6B, when the dummy pattern (refer to DMP of FIG. 7) is not separately disposed on the circuit region CR, the display panel DP on the circuit region CR may more protrude toward the driver chip DC than the display panel DP on the pad regions IPDR and OPDR.

In contrast, referring to an embodiment of the invention depicted in FIG. 7, the dummy pattern DMP may be disposed on the circuit region CR to support the driver chip DC and the display panel DP, and thus the display panel DP may be prevented from protruding toward the driver chip DC. The dummy pattern DMP may support the driver chip DC and the display panel DP to prevent stress from being concentrated on the circuit region CR and to prevent deformation and crack from occurring in the circuit region CR.

In this case, only a portion of a top surface of the dummy pattern DMP may contact the driver chip DC, and depending on the degree of pressurization of the driver chip DC, an entirety of the top surface of the dummy pattern DMP may contact the driver chip DC, and the invention is not limited to an illustrative embodiment.

In comparison between the comparative example and an embodiment of the invention, the display panel DP devoid of the dummy pattern DMP according to the comparative example may be more adjacent to the driver chip DC on the circuit region CR than on other regions and may have more frequent occurrence of deformation and crack.

In addition, the invention is not limited to that shown, and on the pad regions IPDR and OPDR, the dummy pattern DMP may be disposed on a position adjacent to the circuit region CR to thereby prevent the display panel DP from protruding toward the driver chip DC.

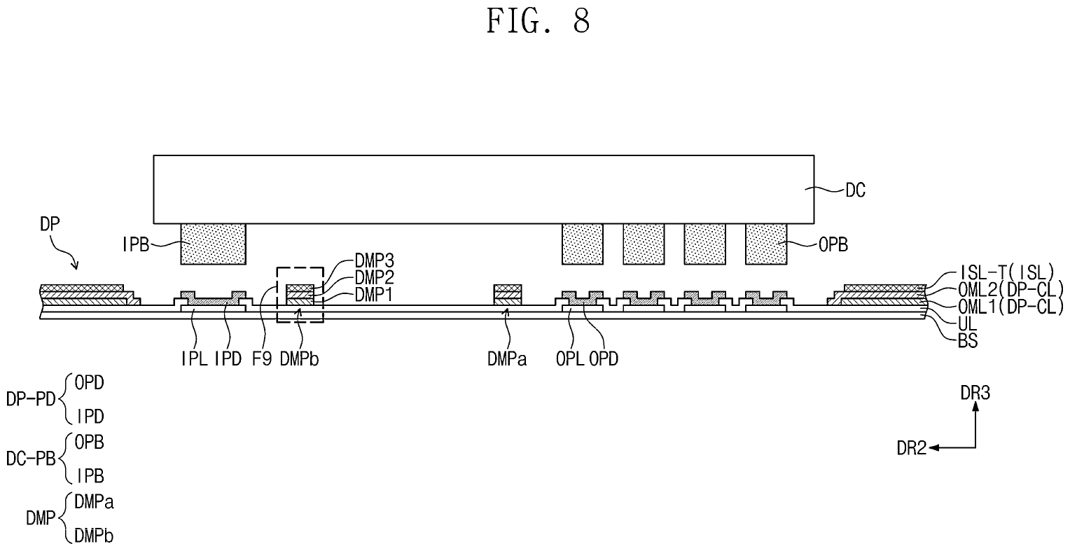

FIG. 8 illustrates a simplified enlarged cross-sectional view showing a comparative example of a chip region of a display device.

Referring to FIG. 8, in an embodiment of the disclosure, the dummy patterns DMP may be disposed on the display panel DP. Although it is illustrated that the dummy patterns DMP are disposed on the display panel DP and spaced apart from the driver chip DC, the dummy patterns DMP may be disposed on the driver chip DC and spaced apart from the display panel DP, and the invention is not limited to an illustrative embodiment.

The upper layer UL may be disposed on the base layer BS, a first dielectric layer OML1 may be disposed on the upper layer UL, a second dielectric layer OML2 may be disposed on the first dielectric layer OML1, and a third dielectric layer ISL-T may be disposed on the second dielectric layer OML2. The first, second, and third dielectric layers OML1, OML2, and ISL-T may each be an organic layer. Although it is illustrated that only three layers (or the first, second, and third dielectric layers OML1, OML2, and ISL-T) are disposed, a plurality of layers may be disposed between neighboring ones of the first, second, and third dielectric layers OML1, OML2, and ISL-T, and the invention is not limited to an illustrative embodiment.

In an embodiment of the disclosure, the first dielectric layer OML1 may correspond to the fifth dielectric layer OML1 depicted in FIG. 3B, the second dielectric layer OML2 may correspond to the sixth dielectric layer OML2 depicted in FIG. 3B, and the third dielectric layer ISL-T may correspond to the third sensor dielectric layer ISL-T depicted in FIG. 3B.

In an alternative embodiment, each of the first and second dielectric layers OML1 and OML2 may correspond to one dielectric layer of a plurality of layers included in the circuit element layer DP-CL, the display element layer DP-ED, the encapsulation layer TFE, and the input sensor ISU depicted in FIG. 3B, and the invention is not limited to an illustrative embodiment.

The dummy pattern DMP may be disposed on the upper layer UL. Pad lines OPL and IPL may be disposed on the upper layer UL. The pads OPD and IPD may be disposed on the upper layer UL and the pad lines OPL and IPL.

Although it is illustrated that the dummy pattern DMP is disposed on the display panel DP and spaced apart from the driver chip DC, the dummy pattern DMP may be disposed on the driver chip DC and spaced apart from the display panel DP, and the invention is not limited to an illustrative embodiment.

In an embodiment of the disclosure, a height of the dummy pattern DMP may be greater than those of the pads OPD and IPD. The height of the dummy pattern DMP may be less than those of the bumps OPB and IPB. As the height of the dummy pattern DMP is less than those of the bumps OPB and IPB, after the bonding between the pads OPD and IPD and the bumps OPB and IPB, the dummy pattern DMP may be prevented from pressurizing the driver chip DC with more than a preset degree in a height direction of the dummy pattern DMP, which may result in prevent of additional deformation of the display panel DP. In an alternative embodiment, the height of the dummy pattern DMP may be the same as those of the bumps OPB and IPB, and the invention is not limited to an illustrative embodiment.

The dummy pattern DMP may include a plurality of layers. The dummy pattern DMP may include a first dummy layer DMP1 disposed on the upper layer UL, a second dummy layer DMP2 disposed on the first dummy layer DMP1, and a third dummy layer DMP3 disposed on the second dummy layer DMP2.

In an embodiment of the disclosure, the first dummy layer DMP1 and the second dummy layer DMP2 may include a material the same as that of one of dielectric layers included in the display panel DP. In addition, the third dummy layer DMP3 may include a material the same as that of one of dielectric layers included in the input sensor ISU. In an alternative embodiment, one or both of the first and second dummy layers DMP1 and DMP2 may include a material the same as that of a dielectric layer of the input sensor ISU, and the invention is not limited to an illustrative embodiment.

In an embodiment, the first dummy layer DMP1 may include the same material as that of the first dielectric layer OML1, and the second dummy layer DMP2 may include the same material as that of the second dielectric layer OML2, for example. The third dummy layer DMP3 may include the same material as that of the third dielectric layer ISL-T.

However, the first, second, and third dummy layers DMP1, DMP2, and DMP3 are not limited to the aforementioned configuration. The second dummy layer DMP2 may include the same material as that of the pixel definition layer PDL. In an embodiment, unlike the aforementioned configuration, the first, second, and third dummy layers DMP1, DMP2, and DMP3 may be ones of dielectric layers or organic layers of the display device DD, for example, and the invention is not limited to an illustrative embodiment.

The same process may be used for forming layers of the first, second, and third dummy layers DMP1, DMP2, and DMP3 simultaneously with dielectric layers of the display panel DP or the input sensor ISU, and the layers may include the same materials as those of the dielectric layers of the display panel DP or the input sensor ISU. A mask may have various patterns used for depositing or patterning each of the layers, and thus the dummy layers DMP1, DMP2, and DMP3 may be formed in the same process used for forming the dielectric layers.

In an embodiment of the disclosure, the first, second, and third dummy layers DMP1, DMP2, and DMP3 may have their lateral surfaces that are substantially aligned with each other in the third direction DR3.

For convenience of description, it is illustrated that the dummy pattern DMP includes three dummy layers DMP1, DMP2, and DMP3, but the number of dummy layers included in the dummy pattern DMP may be less than or greater than three without being limited to three, and the invention is not limited to an illustrative embodiment.

In an embodiment of the disclosure, the dummy pattern DMP may be provided in plural. The first dummy pattern DMPa of the dummy pattern DMP may be disposed adjacent to the output bumps OPB and the output pads OPD. The second dummy pattern DMPb of the dummy pattern DMP may be disposed adjacent to the input bumps IPB and the input pads IPD.

The first dummy pattern DMPa and the second dummy pattern DMPb may differ from each other only in terms of arrangement position, but on the pad region PDR or the circuit region CR, the first dummy pattern DMPa and the second dummy pattern DMPb may be disposed on positions where a stress is concentrated on the display panel DP, and the invention is not limited to an illustrative embodiment.

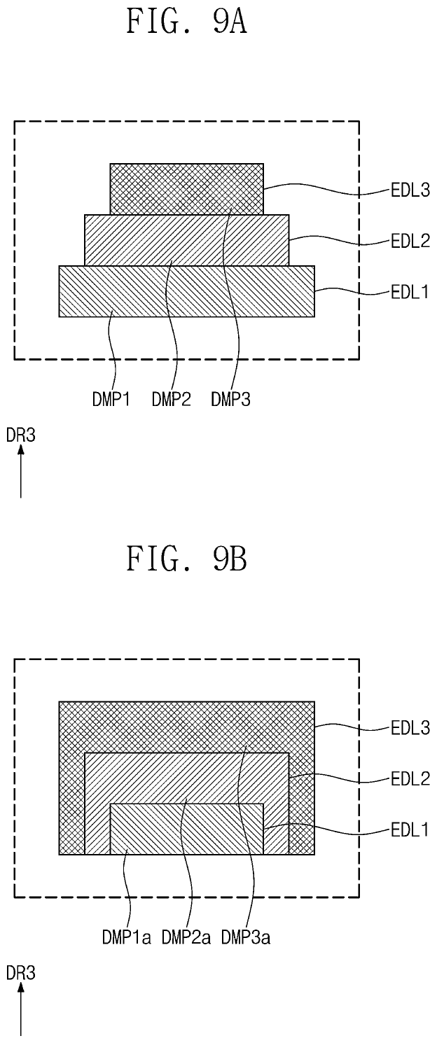

FIGS. 9A and 9B illustrate enlarged cross-sectional views of an area F9 the dummy pattern DMP of FIG. 8 according to the invention. Although FIGS. 9A and 9B depict the dummy pattern DMP includes or consists of three layers, the number of layers of the dummy pattern DMP may be less than or greater than three without being limited to that shown, and the invention is not limited to an illustrative embodiment.

Referring to FIG. 9A, there may be defined a step difference between a lateral surface EDL1 of the first dummy layer DMP1 and a lateral surface EDL2 of the second dummy layer DMP2 in the dummy pattern DMP. A step difference may be defined between the lateral surface EDL2 of the second dummy layer DMP2 and a lateral surface EDL3 of the third dummy layer DMP3.

As shown in FIG. 9A, the lateral surface EDL1 of the first dummy layer DMP1 may protrude further than the lateral surface EDL2 of the second dummy layer DMP2, and the lateral surface EDL2 of the second dummy layer DMP2 may protrude further than the lateral surface EDL3 of the third dummy layer DMP3.

Although it is illustrated a case where a planar area of the first dummy layer DMP1 is greater than that of the second dummy layer DMP2 and where the planar area of the second dummy layer DMP2 is greater than that of the third dummy layer DMP3, the planar area of the first dummy layer DMP1 may be less than that of the second dummy layer DMP2, and the invention is not limited to an illustrative embodiment.

Referring to FIG. 9B, a second dummy layer DMP2a may cover a lateral surface EDL1 of a first dummy layer DMP1a of the dummy pattern DMP, and a third dummy layer DMP3a may cover a lateral surface EDL2 of the second dummy layer DMP2a.

An alignment relationship between the lateral surfaces EDL1, EDL2, and EDL3 of the first, second, and third dummy layers DMP1a, DMP2a, and DMP3a may be changed depending on processes for forming layers of the first, second, and third dummy layers DMP1a, DMP2a, and DMP3a, and the invention is not limited to an illustrative embodiment.

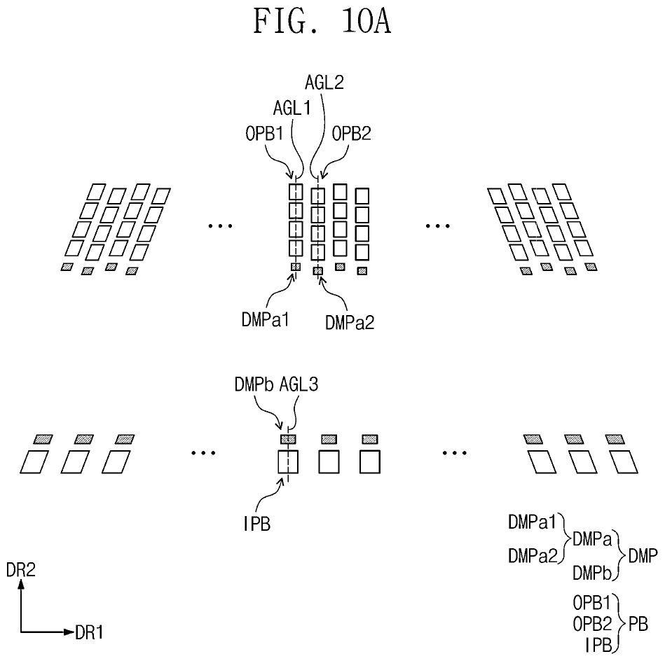

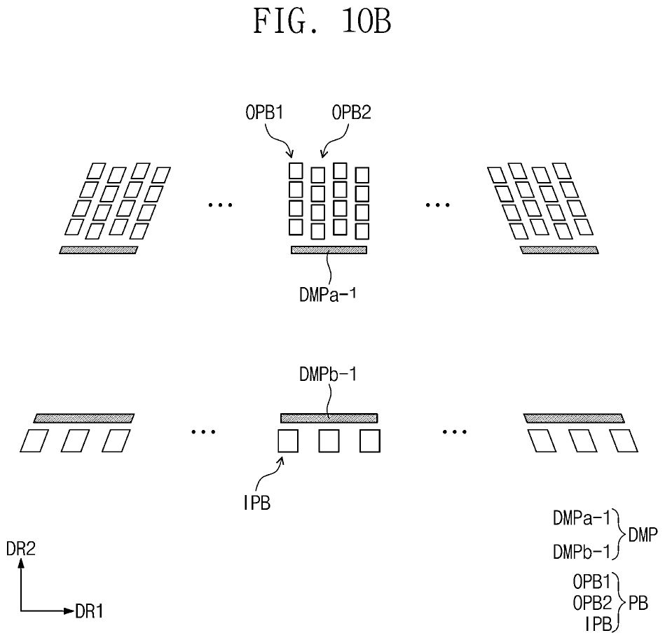

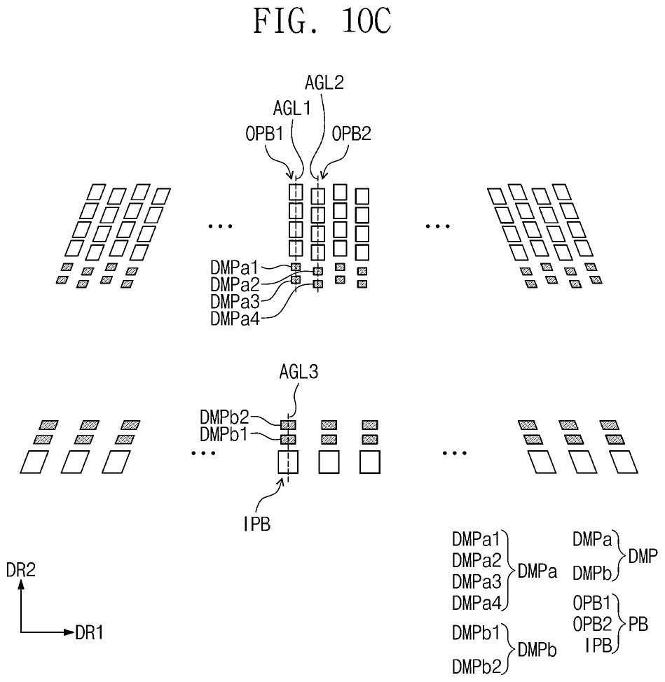

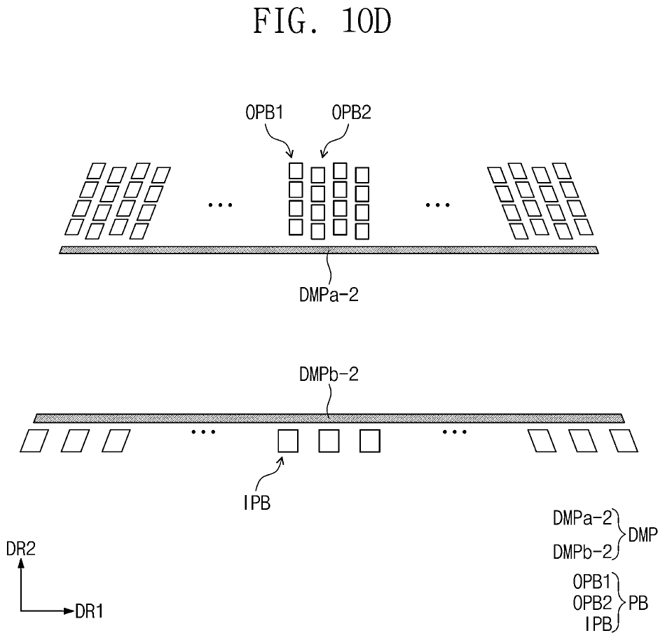

FIGS. 10A to 10D illustrate simplified views showing an arrangement relationship between the bumps PB and the dummy patterns DMP according to the invention.

In FIGS. 10A to 10D, the illustration of the output pads OPD and the input pads IPD is omitted for convenience of description, and in a plan view, the omitted output pads OPD and the omitted input pads IPD may be disposed to overlap the output bumps OPB and the input bumps IPB, respectively.

Referring to FIG. 10A, the first dummy pattern DMPa may include a plurality of dummy members DMPa1 and DMPa2. In an embodiment, the first dummy pattern DMPa may include a plurality of 1-1^{st} dummy members DMPa1 and a plurality of 1-2^{nd} dummy members DMPa2, for example. The 1-1^{st} dummy members DMPa1 and the 1-2^{nd} dummy members DMPa2 may be alternately arranged along the first direction DR1. The 1-2^{nd} dummy members DMPa2 may be shifted in the second direction DR2 at a predetermined distance from the 1-1^{st} dummy members DMPa1.

The second dummy pattern DMPb may include a plurality of dummy members DMPb. The plurality of dummy members DMPb may be arranged along the first direction DR1.

In an embodiment of the disclosure, the first bumps OPB1 and the 1-1^{st} dummy members DMPa1 may be aligned along a first alignment line AGL1 that intersects the first direction DR1. The second bumps OPB2 and the 1-2^{nd} dummy members DMPa2 may be aligned along a second alignment line AGL2 that intersects the first direction DR1. The first alignment line AGL1 and the second alignment line AGL2 may be directed in directions that are parallel or crossed to each other, and the invention is not limited to an illustrative embodiment.

Ones of the input bumps IPB and the dummy members DMPb may be aligned along a third alignment line AGL3 or a different alignment line that intersects the first direction DR1.

A length (or width) in the first direction DR1 of each of the dummy patterns DMP may be the same as or less than a length (or width) in the first direction DR1 of each of the bumps OPB and IPB or the pads (refer to OPD and IPD of FIG. 5A).

When the driver chip (refer to DC of FIG. 4) is pressurized against the display panel (refer to DP of FIG. 4) by placing the pads (refer to PD of FIG. 5A), the bumps PB, and the dummy patterns DMP along alignment lines, the second adhesive layer (refer to AF-D of FIG. 4) disposed between the driver chip (refer to DC of FIG. 4) and the display panel (refer to DP of FIG. 4) may be allowed to easily spread from an inside to an outside of the chip region (refer to DCA of FIG. 4).

In addition, the dummy patterns DMP may have their width less than that of the bumps PB or the pads PD, and it may thus be possible to prevent hindrance of outward spread of the second adhesive layer (refer to AF-D of FIG. 4).

Referring to FIG. 10B, a plurality of dummy patterns DMPa-1 and DMPb-1 may be provided, and ones of the plurality of dummy patterns DMPa-1 and DMPb-1 may be spaced apart from each other along the first direction DR1.

In an embodiment of the disclosure, in the second direction DR2, one of the dummy patterns DMPa-1 and DMPb-1 may overlap a plurality of bumps PB or a plurality of pads (refer to PD of FIG. 5A). As shown in drawing figures, one dummy pattern DMPa-1 may overlap a plurality of columns of the first bumps OPB1 and a plurality of columns of the second bumps OPB2, or may overlap one column of the first bumps OPB1 and one column of the second bumps OPB2, and the invention is not limited to an illustrative embodiment.

Referring to FIG. 10C, the first dummy pattern DMPa may include a plurality of dummy members DMPa1, DMPa2, DMPa3, and DMPa4. In an embodiment, the first dummy pattern DMPa may include a plurality of 1-1^{st} dummy members DMPa1, a plurality of 1-2^{nd} dummy members DMPa2, a plurality of 1-3^{rd} dummy members DMPa3, and a plurality of 1-4^{th} dummy members DMPa4. The 1-1^{st} dummy members DMPa1 and the 1-2^{nd} dummy members DMPa2 may be alternately arranged along the first direction DR1, for example. The 1-3^{rd} dummy members DMPa3 and the 1-4^{th} dummy members DMPa4 may be alternately arranged along the first direction DR1. The 1-3^{rd} dummy members DMPa3 may be spaced apart in the second direction DR2 at a predetermined interval from the 1-1^{st} dummy members DMPa1, and the 1-4^{th} dummy members DMPa4 may be spaced apart in the second direction DR2 at a predetermined interval from the 1-2^{nd} dummy members DMPa2.

The 1-2^{nd} dummy members DMPa2 may be shifted in the second direction DR2 at a predetermined distance from the 1-1^{st} dummy members DMPa1, and the 1-4^{th} dummy members DMPa4 may be shifted in the second direction DR2 at a predetermined distance from the 1-3^{rd} dummy members DMPa3.

The second dummy pattern DMPb may include a plurality of dummy members DMPb1 and DMPb2. In an embodiment, the second dummy pattern DMPb may include a plurality of 2-1^{st} dummy members DMPb1 and a plurality of 2-2^{nd} dummy members DMPb2. The 2-1^{st} dummy members DMPb1 may be arranged along the first direction DR1, and likewise the 2-2^{nd} dummy members DMPb2 may be arranged along the first direction DR1, for example. The 2-2^{nd} dummy members DMPb2 may be spaced apart in the second direction DR2 at a predetermined interval from the 2-1^{st} dummy members DMPb1.

In an embodiment of the disclosure, the first bumps OPB1, the 1-1st dummy members DMPa1, and the 1-3^{rd} dummy members DMPa3 may be aligned along a first alignment line AGL1 that intersects the first direction DR1. The second bumps OPB2, the 1-2^{nd} dummy members DMPa2, and the 1-4^{th} dummy members DMPa4 may be aligned along a second alignment line AGL2 that intersects the first direction DR1. The first alignment line AGL1 and the second alignment line AGL2 may be directed in directions that are parallel or crossed to each other, and the invention is not limited to an illustrative embodiment.

The input bumps IPB, the 2-1^{st} dummy members DMPb1, and 2-2^{nd} dummy members DMPb2 may be aligned along a third alignment line AGL3 that intersects the first direction DR1.

When the driver chip (refer to DC of FIG. 4) is pressurized against the display panel (refer to DP of FIG. 4) by placing the pads (refer to PD of FIG. 5A), the bumps PB, and the dummy patterns DMP along alignment lines, the second adhesive layer (refer to AF-D of FIG. 4) disposed between the driver chip (refer to DC of FIG. 4) and the display panel (refer to DP of FIG. 4) may be allowed to easily spread from an inside to an outside of the chip region (refer to DCA of FIG. 4).

Referring to FIG. 10D, a plurality of dummy patterns DMPa-2 and DMPb-2 may be provided, and the plurality of dummy patterns DMPa-2 and DMPb-2 may be spaced apart from each other along the second direction DR2.

In an embodiment of the disclosure, in the second direction DR2, one of the dummy patterns DMPa-2 and DMPb-2 may overlap a plurality of bumps PB or a plurality of pads (refer to PD of FIG. 5A). In comparison with the embodiment of the invention depicted in FIG. 10B, the embodiment of FIG. 10D may include the plurality of dummy patterns DMPa-2 and DMPb-2 which are arranged along the second direction DR2 and each of which has a single shape that is unitary along the first direction DR1.

Although it is illustrated a case where each of a first dummy pattern DMPa-2 and a second dummy pattern DMPb-2 is provided in singular, each of the first dummy pattern DMPa-2 and the second dummy pattern DMPb-2 may be provided in plural, and the invention is not limited to an illustrative embodiment.

In a display device in an embodiment of the disclosure, a driver chip may be safely disposed (e.g., mounted) on a substrate without the occurrence of crack or fracture of the substrate.

In a display device in an embodiment of the disclosure, it may be possible to contrive microminiaturization of the display device and to reduce manufacturing cost.

Although the embodiments have been described with reference to a number of illustrative examples thereof, it will be understood by those of ordinary skill in the art that various changes in form and details may be made without departing from the spirit and scope of the invention as set forth in the following claims. Thus, the technical scope of the invention is not limited by the embodiments and examples described above, but by the following claims.

What is claimed is:

1. A display device comprising:
a display panel including:
a plurality of pixels;
a plurality of first row output pads electrically connected to the plurality of pixels and arranged along a first direction;
a plurality of second row output pads spaced apart from the plurality of first row output pads in a second direction intersecting the first direction; and
a plurality of input pads spaced apart in the second direction from the plurality of second row output pads and arranged along the first direction;
a driver chip including:
a plurality of first row output bumps arranged along the first direction and coupled to the plurality of first row output pads;
a plurality of second row output bumps spaced apart in the second direction at a first distance from the plurality of first row output bumps and coupled to the plurality of second row output pads; and
a plurality of input bumps spaced apart in the second direction from the plurality of second row output bumps and coupled to the plurality of input pads; and
a dummy pattern between the plurality of second row output pads and the plurality of input pads and in contact with each of the display panel and the driver chip, the dummy pattern including a dielectric material.

2. The display device of claim 1, wherein ones of the plurality of first row output bumps and the plurality of second row output bumps include:
a plurality of first bumps aligned along the first direction; and
a plurality of second bumps aligned along the first direction and shifted in the second direction at a third distance from the plurality of first bumps, the third distance being less than the first distance.

3. The display device of claim 2, wherein the dummy pattern includes:
a plurality of first dummy members aligned along the first direction; and
a plurality of second dummy members aligned along the first direction and shifted in the second direction at a predetermined distance from the plurality of first dummy members.

4. The display device of claim 1, wherein the dummy pattern is spaced apart in the second direction at a second distance from the plurality of second row output bumps, the second distance being greater than the first distance.

5. The display device of claim 3, wherein the plurality of first dummy members and the plurality of second dummy members are alternately arranged along the first direction, and
a distance in the second direction between the plurality of first dummy members and first bumps of the plurality of second row output bumps is equal to a distance in the second direction between the plurality of second dummy members and the plurality of second bumps of the plurality of second row output bumps.

6. The display device of claim 3, wherein a width in the first direction of each of the plurality of first dummy members and the plurality of second dummy members is equal to or less than a width in the first direction of each of the plurality of first row output bumps and the plurality of second row output bumps.

7. The display device of claim 3, wherein
the plurality of first bumps and the plurality of first dummy members are aligned along a first baseline direction that intersects the first direction, and
the plurality of second bumps and the plurality of second dummy members are aligned along a second baseline direction that intersects the first direction.

8. The display device of claim 1, wherein the dummy pattern is provided in plural,
wherein the plurality of dummy patterns is arranged along the second direction, and
wherein at least one of the plurality of dummy patterns is more adjacent to the plurality of input pads than to the plurality of second row output pads.

9. The display device of claim 8, wherein each of the plurality of dummy patterns includes a plurality of dummy members,
wherein ones of the plurality of dummy members are aligned with the plurality of first row output bumps or the plurality of second row output bumps in a direction that intersects the first direction, and wherein others of the plurality of dummy members are aligned with the plurality of input pads in the direction that intersects the first direction.

10. The display device of claim 1, wherein the dummy pattern is provided in plural,
wherein, in the second direction, one of the plurality of dummy patterns overlaps a plurality of pads.

11. The display device of claim 10, wherein, in the first direction, the dummy patterns have a single pattern shape.

12. The display device of claim 10, wherein a height of the dummy pattern is greater than heights of the plurality of first and second row output pads.

13. The display device of claim 1, further comprising an input sensor on the display panel,
wherein each of the display panel and the input sensor includes:
first, second, and third dielectric layers;
a first conductive layer between the first dielectric layer and the second dielectric layer; and
a second conductive layer between the second dielectric layer and the third dielectric layer, and
wherein the dummy pattern includes:
a first dummy layer that includes a dielectric material identical to a material of the first dielectric layer of the display panel;
a second dummy layer on the first dummy layer, the second dummy layer including a material identical to a material of the second dielectric layer of the display panel; and
a third dummy layer on the second dummy layer, the third dummy layer including a material identical to a material of the third dielectric layer of the input sensor.

14. The display device of claim 13, wherein lateral surfaces of the first, second, and third dummy layers are aligned with each other.

15. The display device of claim 13, wherein a step difference is defined between lateral surfaces of two neighboring ones of the first, second, and third dummy layers.

16. The display device of claim 13, wherein
the second dummy layer covers a lateral surface of the first dummy layer, and
the third dummy layer covers a lateral surface of the second dummy layer.

17. A display device comprising:
a display panel that including:
a plurality of pixels;
a plurality of first row output pads electrically connected to the plurality of pixels and arranged along a first direction;
a plurality of second row output pads spaced apart from the plurality of first row output pads in a second direction intersecting the first direction; and
a plurality of input pads spaced apart in the second direction from the plurality of second row output pads and arranged along the first direction;
a driver chip including:
a plurality of first row output bumps arranged along the first direction and coupled to the plurality of first row output pads;
a plurality of second row output bumps spaced apart in the second direction at a first distance from the plurality of first row output bumps and coupled to the plurality of second row output pads, and a plurality of input bumps spaced apart in the second direction from the plurality of second row output bumps and coupled to the plurality of input pads; and
a dummy pattern between the plurality of second row output pads and the plurality of input pads, in a plan view, and in contact with each of the display panel and the driver chip,
wherein the dummy pattern is spaced apart in the second direction at a second distance from the plurality of second row output bumps, the second distance being greater than the first distance.

18. The display device of claim 17, wherein the dummy pattern includes a plurality of dummy members,
wherein the plurality of dummy members include:
a plurality of first dummy members aligned along the first direction; and
a plurality of second dummy members aligned along the first direction and shifted in the second direction at a predetermined distance from the plurality of first dummy members.

19. The display device of claim 18, wherein ones of the plurality of first row output bumps and the plurality of second row output bumps include:
a plurality of first bumps aligned along the first direction; and
a plurality of second bumps aligned along the first direction and shifted in the second direction at a third distance from the plurality of first bumps, the third distance being less than the first distance,
wherein a distance in the second direction between the plurality of first dummy members and the plurality of first bumps of the plurality of second row output bumps is equal to a distance in the second direction between the plurality of second dummy members and the plurality of second bumps of the plurality of second row output bumps.

20. The display device of claim 19, wherein
the plurality of first bumps and the plurality of first dummy members are aligned along a direction that intersects the first direction, and
the plurality of second bumps and the plurality of second dummy members are aligned along the direction that intersects the first direction.
